(19) United States
(12) Patent Application Publication
(10) Pub. No.: US 2005/0022740 A1
(43) Pub. Date: Feb. 3, 2005

(54) Plasma processing system and cleaning method for the same

(75) Inventor: Akitsugu Hatano, Nara (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/899,030

(22) Filed: Jul. 27, 2004

(30) Foreign Application Priority Data
Jul. 30, 2003 (JP) 2003-283083
Jun. 9, 2004 (JP) 2004-171598

(51) Int. Cl. C23C 16/00

(52) U.S. Cl. 118/723 E

(57) ABSTRACT

A plasma processing system includes a processing chamber, a substrate holder provided within the processing chamber for holding a target substrate, a composite electrode provided within the processing chamber so as to oppose the substrate holder and having a plurality of first electrodes and second electrodes for generating plasma, and a gas supply section for supplying a material gas into the processing chamber. The system further includes a plasma region increasing/reducing section for increasing or reducing a plasma region formed in the processing chamber, and a cleaning section for plasma cleaning the inside of the processing chamber by using plasma generated in the plasma region increased or reduced by the plasma region increasing/reducing section. Thus, the quality of a film to be deposited can be improved by eliminating ion impact against the target substrate, and the system cost can be lowered by efficiently removing, with a simple structure, particles produced in the processing chamber.

### CROSS REFERENCE TO RELATED APPLICATIONS

This Nonprovisional application claims priority under 35 U.S.C. §119(a) on Patent Application No. 2003-283083 filed in Japan on Jul. 30, 2003 and Patent Application No. 2004-171598 filed in Japan on Jun. 9, 2004, the entire contents of which are hereby incorporated by reference.

### BACKGROUND OF THE INVENTION

The present invention relates to a plasma processing system that performs, in a processing chamber, plasma processing by plasma-activated chemical vapor deposition, dry etching, ashing and the like and cleans the inside of the processing chamber with plasma, and a plasma cleaning method for the system.

The plasma-activated chemical vapor deposition (hereinafter referred to as the plasma CVD) for depositing a semiconductor film or the like by using plasma is conventionally known. A conventional parallel plate type plasma processing system for depositing a film on a target substrate by the plasma CVD will be described with reference to FIGS. 28 and 29.

The parallel plate type plasma processing system includes a processing chamber 5, that is, a vacuum vessel, and electrodes 2a and 2b corresponding to two conducting plates disposed in parallel to each other within the processing chamber 5.

As shown in FIG. 29, the electrode 2a is a cathode electrode (discharge electrode) fixedly supported on an electrode support 22 provided in the processing chamber, and the electrode 2b is an anode electrode facing upward so as to oppose the cathode electrode 2a. The cathode electrode 2a is connected to a power circuit 1 for applying a voltage for generating plasma 11. As the power circuit 1, electric energy with a high frequency of, for example, 13.56 MHz or the like is generally used. The anode electrode 2b is electrically grounded.

A target substrate 4 of silicon, glass or the like to be processed is provided on the lower face of the anode electrode 2b. The cathode electrode 2a is provided with a plurality of gas inlets 6 so that a material gas supplied from a gas supply unit 13 can be supplied through the gas inlets 6 into a space between the cathode electrode 2a and the anode electrode 2b. Also, the processing chamber 5 is connected to a vacuum pump 10.

The power circuit 1 is driven to apply a given voltage to the cathode electrode 2a. Furthermore, the material gas is allowed to flow through the gas inlets 6 into the space between the cathode electrode 2a and the anode electrode 2b.

Thus, an electric field is generated between the electrodes 2a and 2b, and the plasma 11 corresponding to a glow discharge phenomenon is generated due to dielectric breakdown of the electric field. A portion in the vicinity of the cathode electrode 2a in which a comparatively large electric field is formed is designated as a cathode sheath. In and in the vicinity of the cathode sheath, electrons included in the plasma 11 are accelerated to impel dissociation of the material gas, so as to produce radicals. The radicals are diffused toward the target substrate 4 loaded on the anode electrode 2b having the ground potential as shown with arrows R in FIG. 29, so as to deposit on the face of the target substrate 4. In this case, the processing chamber 5 is evacuated by the vacuum pump 10 to have a reduced pressure. Also, in the vicinity of the anode electrode 2b, there is a portion in which an electric field with a certain magnitude is formed, and this portion is designated as an anode sheath.

In the case where, for example, amorphous silicon is deposited on the face of the target substrate 4, a SiH₄ gas is used as the material gas 14. Radicals including Si such as SiH₃ are produced through the glow discharge plasma, so as to deposit an amorphous silicon film on the target substrate 4 by using these radicals.

In this manner, the parallel plate type plasma processing system is simple and easy to operate, and hence is suitably used for fabricating a variety of electronic devices such as integrated circuits, liquid crystal displays, organic electroluminescence devices and solar batteries. For example, in fabrication of an active matrix liquid crystal display, a TFT (Thin Film Transistor) working as a switching device is formed by using the aforementioned plasma processing system. In a TFT, a semiconductor film or a gate oxide film made of an amorphous silicon film or a silicon nitride film plays a significant role. In order to make the gate oxide film or the like sufficiently exhibit its function, it is indispensable to highly precisely form a thin film. Alternatively, for example, in fabrication of an organic electroluminescence device, after forming an organic thin film, it is necessary to highly precisely form a transparent insulating film as a protection film for protecting the face of the organic thin film exposed to the air. Similarly, in fabrication of a solar battery, after forming a solar battery layer, it is significant to highly precisely form a protection film for protecting the face of the solar battery film exposed to the air.

In the conventional parallel plate type plasma processing system, however, there is a limit in the precision in the deposition due to its structure, and therefore, it is difficult to employ this plasma processing system for fabricating a highly precise electronic device such as a liquid crystal display or an amorphous solar battery.

Specifically, in the deposition performed by the parallel plate type plasma processing system, since the target substrate is provided on the ground electrode (i.e., the anode electrode), the anode sheath of the electric field is always formed on the face of the target substrate. In the anode sheath, ions included in the plasma are accelerated, and therefore, the deposition face on the target substrate is subjected to ion impact, which degrades the film to be deposited.

Therefore, for the purpose of depositing a high quality thin film by suppressing the ion impact against a target substrate, a composite electrode type plasma processing system in which a plurality of anode electrodes and cathode electrodes for generating discharge plasma are alternately provided so as to oppose a target substrate is known (for example, see Japanese Laid-Open Patent Publication No. 2001-338885). In this composite electrode type plasma processing system, the target substrate is separated from the anode electrodes, and therefore, ions included in the plasma are never accelerated toward the face of the target substrate. As a result, the ion impact against the deposition face caused by the influence of the anode electrodes is suppressed, so that a high quality thin film can be deposited as compared with the case where the parallel plate type plasma processing system is used.

The parallel plate type plasma processing system and the composite electrode type plasma processing system have, however, a problem that there is a fear of a film defect caused in a deposited film. Specifically, the plasma is unavoidably spread to some extent within the processing chamber during the deposition, and therefore, unwanted films are unavoidably deposited on portions other than the target substrate such as the inner walls of the processing chamber. Such unwanted films have comparatively low adhesion, and when their thicknesses are increased through repeated deposition, they are peeled off to form flakes, which become sources of particles. Also, in a region within the processing chamber 5 where the temperature is comparatively low or where the material gas tends to stay, the radicals are polymerized in the gas phase so as to produce a powder. This powder is increased through the repeated deposition and hence becomes the source of particles. Such particles are incorporated into the film to be deposited on the target substrate and thus cause a film defect.

Therefore, in order to prevent the film defect and improve the productivity, plasma cleaning for removing unwanted films and products such as the powder produced within the processing chamber is conventionally performed. For the plasma cleaning, for example, in the case where an amorphous silicon film is deposited in the processing chamber, fluorine radicals are produced by supplying a NF₃ gas as a reaction gas into the processing chamber and generating the glow discharge plasma, so as to clean the inside of the processing chamber with the fluorine radicals.

In the conventional composite electrode type plasma processing system in particular, however, it is difficult to sufficiently clean the inside of the processing chamber with plasma. Specifically, the plasma region formed between the cathode electrode and the anode electrode within the processing chamber is substantially the same in a depositing operation and a cleaning operation, and is limited to a comparatively small region in the vicinity of the composite electrode. Furthermore, since the fluorine radicals used in the plasma cleaning have short lifetime, the fluorine radicals are difficult to diffuse into a region other than the region in the vicinity of the electrode within the processing chamber. As a result, it is very difficult to sufficiently clean all unwanted films deposited within the processing chamber.

On the other hand, the parallel plate type plasma processing system is conventionally provided with a cleaning electrode disposed on the inner wall of the processing chamber (for example, see Japanese Laid-Open Patent Publication No. 2002-57110). In this case, plasma for cleaning is generated between the cleaning electrode and the inner wall face of the processing chamber, so as to clean the inner wall of the processing chamber with the plasma.

Therefore, it can be considered that the composite electrode type plasma processing system is provided with a cleaning electrode. However, although the cleaning effect for the processing chamber can be improved by providing the cleaning electrode, the cost of the system is disadvantageously increased because it is necessary to additionally provide the cleaning electrode itself on the inner wall of the processing chamber.

Furthermore, there is another problem that merely the inner wall on which the cleaning electrode is provided can be cleaned. (In other words, the other inner walls not provided with the cleaning electrode cannot be cleaned). Therefore, if the whole inner walls of the processing chamber are to be plasma cleaned, the cleaning electrode should be provided over the whole inner walls of the processing chamber. Accordingly, the aforementioned problem about the system cost becomes more serious.

The present invention was devised in consideration of these conventional disadvantages and problems, and an object of the invention is, in a plasma processing system and a plasma cleaning method for the same, improving the quality of a deposited film by eliminating ion impact against a target substrate and reducing the system cost by efficiently removing, with a simple structure, particles produced within a processing chamber.

Other objects of the invention are forming different kinds of high quality films in one and the same plasma processing system by controlling ion impact against a target substrate in such a manner that the quality of a deposited film is improved by eliminating the ion impact against the target substrate and that the ion impact is applied to the target substrate in deposition requiring the ion impact; improving the performance of the plasma processing system; and lowering the system cost.

### SUMMARY OF THE INVENTION

In order to achieve the aforementioned objects, according to the present invention, plasma cleaning is performed with a plasma region formed in a processing chamber increased or reduced.

Specifically, the plasma processing system of this invention includes a processing chamber; a substrate holder provided within the processing chamber for holding a target substrate; a composite electrode provided within the processing chamber to oppose the substrate holder and having a plurality of discharge electrodes for generating plasma; material gas supply means for supplying a material gas into the processing chamber; plasma region increasing/reducing means for increasing or reducing a plasma region formed within the processing chamber; and cleaning means for plasma cleaning an inside of the processing chamber by using plasma generated in the plasma region increased or reduced by the plasma region increasing/reducing means.

The cleaning means preferably includes reaction gas supply means for supplying, into the processing chamber, a reaction gas to be used for plasma cleaning the inside of the processing chamber, and the plasma region increasing/reducing means may include a pressure control mechanism for controlling a pressure within the processing chamber to which the reaction gas is supplied by the reaction gas supply means.

The pressure control mechanism preferably increases or reduces the pressure within the processing chamber.

The pressure control mechanism preferably controls the pressure within the processing chamber in such a manner that a period when a given first pressure is kept is longer than a period when a second pressure lower than the first pressure is kept.

The substrate holder may be constructed as an electrode, and the plasma region increasing/reducing means may include a switching device for switching a voltage applied state of the substrate holder and the discharge electrodes between a first voltage applied state for generating plasma between the discharge electrodes and a second voltage applied state for generating plasma between the composite electrode and the substrate holder.

The switching device preferably switches the voltage applied state alternately between the first voltage applied state and the second voltage applied state.

The switching device preferably switches the voltage applied state in such a manner that a period when the first voltage applied state is kept is longer than a period when the second voltage applied state is kept.

The plasma region increasing/reducing means may include an adjusting mechanism for adjusting a distance between the substrate holder and the composite electrode.

The composite electrode is preferably removably provided in the processing chamber.

The composite electrode preferably includes an inter-electrode insulating portion for insulating the plurality of discharge electrodes from one another, and the plurality of discharge electrodes preferably include first electrodes and second electrodes alternately arranged.

The composite electrode may include a first electrode and a second electrode disposed closer to the target substrate than the first electrode, so that merely faces of the first electrode and the second electrode visible from a normal direction of the target substrate may function as plasma discharge faces.

The first electrode and the second electrode may be formed in the shape of stripes extending in parallel to one another.

A voltage applied to the composite electrode preferably has a frequency not less than 100 kHz and not more than 300 MHz.

Alternatively, the plasma processing system of this invention includes a processing chamber; a substrate holder provided within the processing chamber for holding a target substrate; a composite electrode provided within the processing chamber to oppose the substrate holder and having a plurality of discharge electrodes for generating plasma; material gas supply means for supplying a material gas into the processing chamber; and plasma region increasing/reducing means for increasing or reducing a plasma region formed within the processing chamber, and a film is deposited on the target substrate by using plasma generated in the plasma region increased or reduced by the plasma region increasing/reducing means.

The substrate holder may be constructed as an electrode, and the plasma region increasing/reducing means may include a switching device for switching a voltage applied state of the substrate holder and the discharge electrodes between a first voltage applied state for generating plasma between the discharge electrodes and a second voltage applied state for generating plasma between the composite electrode and the substrate holder.

The plasma region increasing/reducing means may include an adjusting mechanism for adjusting a distance between the substrate holder and the composite electrode.

The composite electrode preferably includes an inter-electrode insulating portion for insulating the plurality of discharge electrodes from one another, and the plurality of discharge electrodes preferably include first electrodes and second electrodes alternately arranged.

The composite electrode may include a first electrode and a second electrode disposed closer to the target substrate than the first electrode, so that merely faces of the first electrode and the second electrode visible from a normal direction of the target substrate may function as plasma discharge faces.

The first electrode and the second electrode may be formed in the shape of stripes extending in parallel to one another.

A voltage applied to the composite electrode preferably has a frequency not less than 100 kHz and not more than 300 MHz.

Furthermore, the cleaning method of this invention for a plasma processing system for cleaning an inside of a processing chamber of the plasma processing system, which includes a substrate holder provided within the processing chamber for holding a target substrate, a composite electrode provided within the processing chamber to oppose the substrate holder and having a plurality of discharge electrodes for generating plasma, and material gas supply means for supplying a material gas into the processing chamber, includes a step of removing products from the processing chamber by supplying a cleaning reaction gas into the processing chamber with a plasma region formed in the processing chamber increased or reduced.

The cleaning reaction gas used for plasma cleaning the inside of the processing chamber may be supplied into the processing chamber and the plasma region may be increased or reduced by controlling a pressure within the processing chamber.

The pressure within the processing chamber is preferably increased or reduced.

The pressure within the processing chamber may be controlled in such a manner that a period when a given first pressure is kept is longer than a period when a second pressure lower than the first pressure is kept.

The plasma region is preferably increased or reduced by switching a voltage applied state of the substrate holder constructed as an electrode and the plurality of discharge electrodes between a first voltage applied state for generating plasma between the discharge electrodes and a second voltage applied state for generating plasma between the composite electrode and the substrate holder.

The voltage applied state may be switched alternately between the first voltage applied state and the second voltage applied state.

The voltage applied state is preferably switched in such a manner that a period when the first voltage applied state is kept is longer than a period when the second voltage applied state is kept.

The functions of the present invention are as follows:

In the case where the target substrate is subjected to the plasma processing, plasma is generated by applying a given voltage to the discharge electrodes of the composite electrode and a material gas is supplied into the processing chamber by the material gas supply means. At this point, a plasma region is reduced to a comparatively narrow region in the vicinity of the composite electrode by the plasma region increasing/reducing means. Thus, the material gas is dissociated through the plasma so as to produce radicals. The radicals are deposited on the target substrate held by the substrate holder so as to form a film. In this manner, ion impact against the target substrate is suppressed, and hence, a high quality film having a less rough and flat face can be deposited.

Also, in the plasma processing, when the plasma region is increased by the plasma region increasing/reducing means, a film can be deposited on the target substrate with the ion impact applied. In some films such as a silicon nitride film, appropriate ion impact is necessary for forming a dense film. Therefore, according to the present invention, when the appropriate ion impact is necessary, the magnitude of the plasma region is controlled by the plasma region increasing/reducing means, so that a high quality film can be deposited by adjusting the degree of the ion impact against the target substrate. As a result, a plurality of kinds of films can be deposited by using one and the same system with their film qualities improved.

On the other hand, in the case where the processing chamber is subjected to the plasma cleaning, the inside of the processing chamber is plasma cleaned by the cleaning means with the plasma region increased or reduced by the plasma region increasing/reducing means.

When the plasma cleaning is performed with the plasma region increased, the whole inside of the processing chamber can be cleaned. On the other hand, when the plasma cleaning is performed with the plasma region reduced, a specific region within the processing chamber, such as a portion around the composite electrode, can be intensively cleaned.

Furthermore, in the case where the cleaning means includes the reaction gas supply means and the plasma region increasing/reducing means includes the pressure control mechanism, the plasma region is increased or reduced in accordance with the Paschen's law by changing the pressure of the reaction gas within the processing chamber.

According to the Paschen's law, space electric field strength at which discharge can be started is determined by a product of a gas pressure and the length of a discharge path. When the product has a given value, the space electric field strength at which the discharge can be started has the minimum value, and when the product has a larger or smaller value, the space electric field strength at which the discharge can be started is increased.

Specifically, in the case where the voltage applied to the discharge electrodes is constant, when the pressure of the reaction gas within the processing chamber is increased, discharge is caused in a region with a shorter discharge path, and hence, the plasma region is reduced. On the other hand, when the pressure of the reaction gas within the processing chamber is reduced, discharge is caused in a region with a longer discharge path, and hence, the plasma region is increased.

In the case where the period when the pressure within the processing chamber is kept at the comparatively high first pressure is longer than the period when it is kept at the comparatively low second pressure, a period when the plasma region is reduced is longer. Therefore, the portion around the composite electrode or the like can be intensively cleaned over a longer period of time.

Alternatively, when the plasma region increasing/reducing means includes the switching device so as to switch the voltage applied state between the first voltage applied state for generating the plasma between the discharge electrodes and the second voltage applied state for generating the plasma between the composite electrode and the substrate holder, the plasma region can be increased or reduced. Specifically, in the first voltage applied state, the plasma region is comparatively reduced, and in the second voltage applied state, the plasma region is comparatively increased. In the case where the period of the first voltage applied state is longer than the period of the second voltage applied state, a period when the plasma region is reduced is comparatively long.

In the case where the plasma region increasing/reducing means includes the adjusting mechanism, the plasma region can be increased by increasing the distance between the substrate holder and the composite electrode by the adjusting mechanism. On the other hand, the plasma region can be reduced by reducing the distance between the substrate holder and the composite electrode by the adjusting mechanism.

In the case where the composite electrode is removably provided in the processing chamber, the composite electrode can be taken out of the processing chamber to be separately cleaned. Also, a composite electrode having been used for a given period of time can be exchanged with a fresh and new composite electrode, so that the plasma processing can be highly precisely performed without spending time on the cleaning.

Furthermore, in the case where the composite electrode includes the first and second electrodes formed in the shape of stripes and the inter-electrode insulating portion, distances between the electrodes can be uniform so as to obtain stable discharge.

According to the present invention, the inside of the processing chamber is plasma cleaned by the cleaning means with the plasma region increased or reduced by the plasma region increasing/reducing means. Therefore, when the plasma cleaning is performed by the cleaning means with the plasma region increased, the whole inside of the processing chamber can be cleaned. On the other hand, when the plasma cleaning is performed by the cleaning means with the plasma region reduced, a specific region within the processing chamber such as a portion around the composite electrode can be intensively cleaned.

As a result, since the plasma used for depositing a film is generated by the composite electrode, the quality of the deposited film can be improved by eliminating ion impact against the target substrate. In addition, since there is no need to additionally provide a cleaning electrode, products such as particles produced within the processing chamber can be efficiently removed with a simple structure, so as to improve the productivity and lower the system cost.

Furthermore, according to the present invention, a film can be deposited with the plasma region increased or reduced by the plasma region increasing/reducing means. Therefore, highly precise deposition can be performed by depositing a film with the plasma region reduced. In addition, a film that needs appropriate ion impact can be deposited with the plasma region increased so as to attain high quality.

As a result, a plurality of kinds of high quality films can be deposited by using one and the same system with a simple structure, and therefore, the productivity can be improved and the system cost can be lowered.

### BRIEF DESCRIPTION OF THE DRAWINGS

FIG. 1 is a schematic perspective view of a principal part of a plasma processing system according to Embodiment 1;

FIG. 2 is a cross-sectional view of the plasma processing system obtained in a depositing operation performed with a discharge state set to an N state;

FIG. 3 is a front view for showing the appearances of a composite electrode and an electrode support;

FIG. 4 is a cross-sectional view of the composite electrode removed from the electrode support;

FIG. 5 is a schematic perspective view of the plasma processing system obtained in a cleaning operation;

FIG. 6 is a cross-sectional view of the plasma processing system obtained in a cleaning operation performed with the discharge state set to a W state;

FIG. 7 is a time chart for showing changes of switches and a gas pressure within a processing chamber;

FIG. 8 is a time chart for showing changes of switches and a gas pressure employed in Embodiment 2;

FIG. 9 is a cross-sectional view of a plasma processing system obtained in a cleaning operation performed with the discharge state set to the N state;

FIG. 10 is a time chart for showing changes of switches and a gas pressure employed in Embodiment 3;

FIG. 11 is a schematic perspective view of a principal part of a plasma processing system according to Embodiment 4;

FIG. 12 is a time chart for showing changes of switches and a gas pressure employed in Embodiment 4;

FIG. 13 is a cross-sectional view of a plasma processing system according to Embodiment 5 obtained in a depositing operation performed with the discharge state set to the N state;

FIG. 14 is a time chart for showing changes of switches and a gas pressure employed in Embodiment 5;

FIG. 15 is a time chart for showing changes of switches and a gas pressure employed in Embodiment 6;

FIG. 16 is a schematic perspective view of a principal part of a plasma processing system according to Embodiment 7;

FIG. 17 is a cross-sectional view of a plasma processing system obtained in a cleaning operation performed with the discharge state set to the N state;

FIG. 18 is a cross-sectional view of the plasma processing system obtained in a cleaning operation performed with the discharge state set to an M state;

FIG. 19 is a time chart for showing changes of switches and a gas pressure employed in Embodiment 8;

FIG. 20 is a cross-sectional view of a plasma processing system obtained in a cleaning operation performed with the discharge state set to an L state;

FIG. 21 is a cross-sectional view of the plasma processing system obtained in a cleaning operation performed with the discharge state set to the W state;

FIG. 22 is a schematic perspective view of a principal part of a plasma processing system according to Embodiment 10;

FIG. 23 is an enlarged cross-sectional view of a discharge state set to the N state in Embodiment 10;

FIG. 24 is an enlarged cross-sectional view of a discharge state set to the M state in Embodiment 10;

FIG. 25 is a cross-sectional view for showing the structures of a composite electrode and an electrode support according to Embodiment 11;

FIG. 26 is a plan view of the composite electrode of Embodiment 11;

FIG. 27 is a cross-sectional view of the composite electrode removed from the electrode support in Embodiment 11;

FIG. 28 is a schematic perspective view of a principal part of a conventional parallel plate type plasma processing system; and

FIG. 29 is a cross-sectional view of the parallel plate type plasma processing system obtained in a depositing operation.

### DETAILED DESCRIPTION OF THE INVENTION

Preferred embodiments of the invention will now be described with reference to the accompanying drawings. It is noted that the present invention is not limited by any of the following embodiments.

Embodiment 1

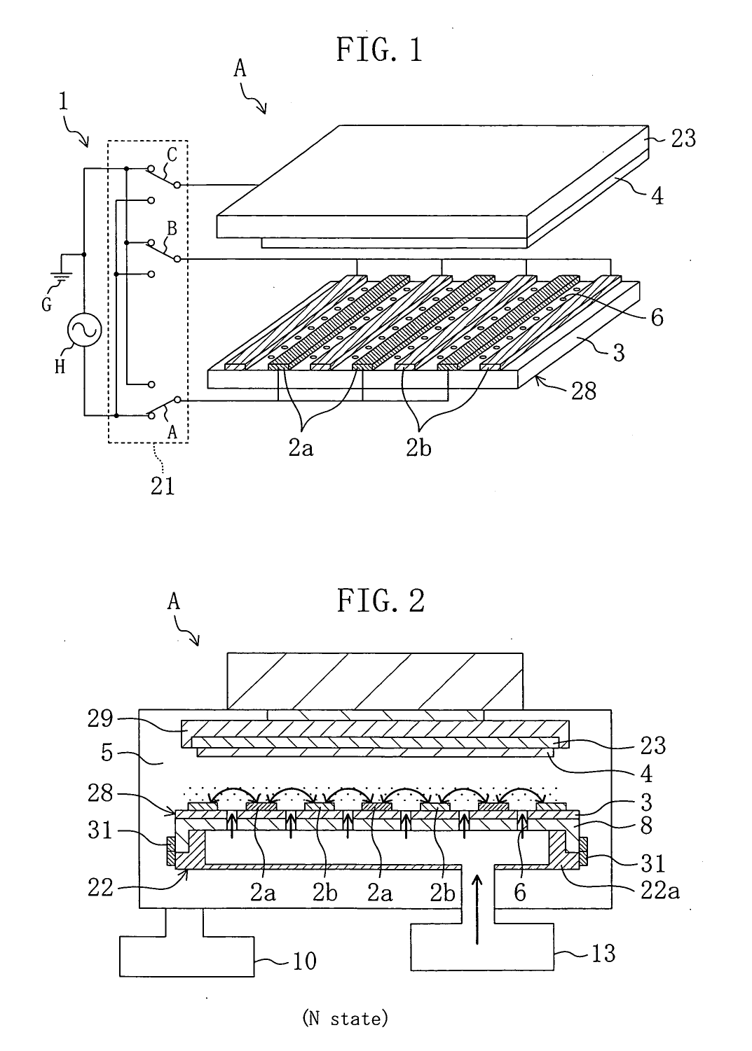

FIGS. 1 through 7 show a plasma processing system according to Embodiment 1. FIG. 1 is a schematic perspective view of a principal part of the plasma processing system and FIG. 2 is a cross-sectional view thereof.

The plasma processing system A includes, as shown in FIG. 2, a processing chamber 5, a substrate holder 23 for holding a target substrate 4 to be processed, a composite electrode 28 for generating plasma, a power circuit unit 1 and a gas supply unit 13 working as material gas supply means. Thus, the plasma processing system A is constructed as a composite electrode type plasma processing system. The target substrate 4 is subjected to plasma processing such as deposition by the plasma CVD within the processing chamber 5, and the inside of the processing chamber 5 is plasma cleaned.

The processing chamber 5 is constructed as a vacuum vessel having a door (not shown) through which the target substrate 4 is taken in/out. The processing chamber 5 is connected to a vacuum pump 10 for evacuating it and reducing the pressure within the processing chamber 5.

The substrate holder 23 is provided inside the processing chamber 5 and is constructed as a plate-like electrode extending substantially horizontally. The substrate holder 23 holds the target substrate 4 on its lower face and is covered with an insulating member 29 except for the lower face. The substrate holder 23 is fixed on the upper inner wall of the processing chamber 5 with the insulating member 29 sandwiched therebetween.

The composite electrode 28 is provided inside the processing chamber 5 so as to oppose the substrate holder 23 as shown in FIG. 2. In other words, the composite electrode 28 opposes the target substrate 4. A distance between the composite electrode 28 and the substrate holder 23 is, for example, 35 mm. The composite electrode 28 includes a base 8 in a concave shape opening downward, an inter-electrode insulating portion 3 provided on the upper face of the base 8 and a plurality of discharge electrodes 2a and 2b provided on the inter-electrode insulating portion 3 at a given interval.

The discharge electrodes 2a and 2b are first electrodes 2a and second electrode 2b as shown in FIGS. 1 and 2. The first electrodes 2a and the second electrodes 2b are formed in the shape of stripes extending in parallel one another when seen from the above, and are alternately disposed on the inter-electrode insulating portion 3. The inter-electrode insulating portion 3 electrically insulates the first electrodes 2a and the second electrodes 2b from each other. Plasma is generated by applying a given voltage to the first electrodes 2a and the second electrodes 2b.

Each of the first electrodes 2a and the second electrodes 2b is made of an aluminum rod with, for example, a width of 6 mm, a height of 3 mm and a length of 80 cm, and the first and second electrodes are alternately arranged at an interval of, for example, 15 mm. The upper face of the base 8 is made of an aluminum plate with a size of 90 cm×100 cm. The inter-electrode insulating portion 3 is made from, for example, ceramics.

In the composite electrode 28, a plurality of gas inlets 6 penetrating through the inter-electrode insulating portion 3 and the base 8 are formed between the first electrodes 2a and the second electrodes 2b adjacent to each other.

An electrode support 22 is provided inside the processing chamber 5 so as to removably support the composite electrode 28 as shown in FIGS. 2 and 4. In other words, the composite electrode 28 is removably provided in the processing chamber 5.

The electrode support 22 includes a concave 22a opening upward. The composite electrode 28 is loaded on the opening of the concave 22a and thus the inside of the concave 22a is closed. In other words, the inside space of the concave 22a closed by the composite electrode 28 constructs a chamber.

On the other hand, the bottom of the concave 22a is connected to the gas supply unit 13. Thus, a gas supplied by the gas supply unit 13 into the concave 22a is introduced into the processing chamber 5 through the gas inlets 6.

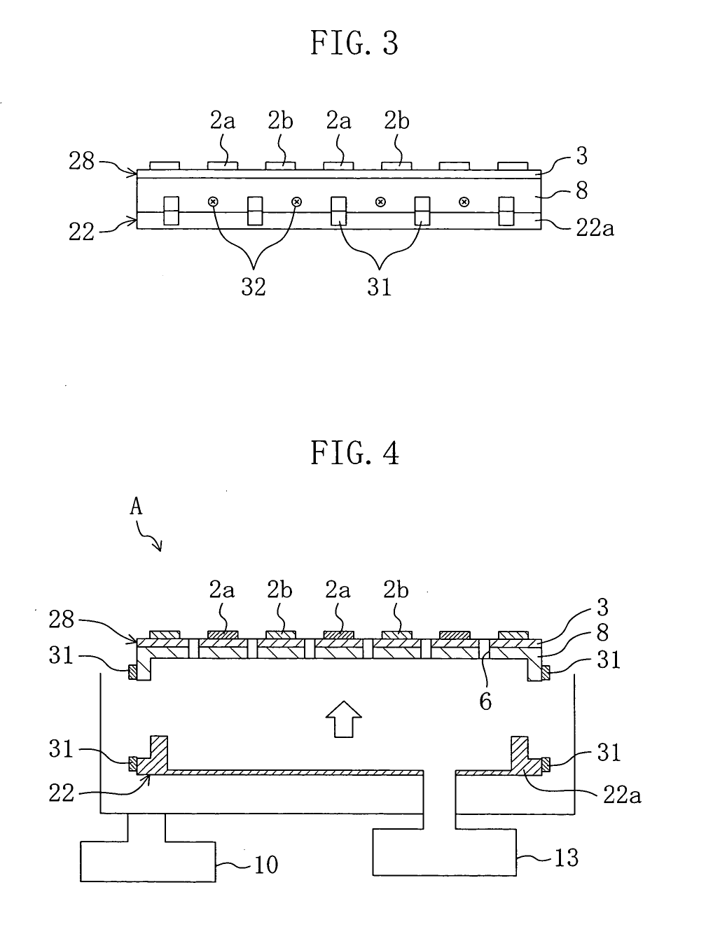

Now, the removable structures of the composite electrode 28 and the electrode support 22 will be described with reference to FIGS. 3 and 4, which are cross-sectional views of the composite electrode 28 and the electrode support 22. The outer peripheral side face of the composite electrode 28 and the outer peripheral side face of the concave 22a of the electrode support 22 are provided with a plurality of clamps 31 disposed at given intervals. The base 8 of the composite electrode 28 is fit on the concave 22a of the electrode support 22 so as to be easily fixed with the clamps 31. Furthermore, the base 8 is more rigidly fixed by being screwed on the concave 22a with screws 32. On the other hand, the composite electrode 28 is removable from the electrode support 22 by loosing the screws 32 and the clamps 31.

The power circuit unit 1 includes a high frequency power source H with a frequency of, for example, 13.56 MHz, a ground G and three switches A, B and C as shown in FIG. 1. The switch A is connected to the first electrodes 2a, the switch B is connected to the second electrodes 2b and the switch C is connected to the substrate holder 23.

The switch A switches the connection of the first electrodes 2a between the high frequency power source H and the ground G. The switch B switches the connection of the second electrodes 2b between the high frequency power source H and the ground G. Also, the switch C switches the connection of the substrate holder 23 between the high frequency power source H and the ground G. Thus, the polarities of the substrate holder 23, the first electrodes 2a and the second electrodes 2b are changeable.

The gas supply unit 13 works as the material gas supply means for supplying, into the processing chamber 5, a material gas, that is, a material for a film to be deposited in a depositing operation as well as works as reaction gas supply means for supplying a reaction gas for plasma cleaning in a cleaning operation. In other words, the gas supply unit 13 supplies both the reaction gas and the material gas into the processing chamber 5.

The plasma processing system A of this embodiment further includes plasma region increasing/reducing means for increasing or reducing a plasma region formed within the processing chamber 5 and cleaning means for plasma cleaning the inside of the processing chamber 5 by using plasma generated in the plasma region increased by the plasma region increasing/reducing means.

The plasma region increasing/reducing means is a switching device 21 for switching the generation state (discharge state) of the plasma generated within the processing chamber between predetermined two states.

The switching device 21 is composed of the three switches A, B and C of the power circuit unit 1. The switching device 21 switches the voltage applied state of the substrate holder 23, the first electrodes 2a and the second electrodes 2b between a first voltage applied state for generating the plasma between the first electrodes 2a and the second electrodes 2b and a second voltage applied state for generating the plasma between the composite electrode 28 and the substrate holder 23.

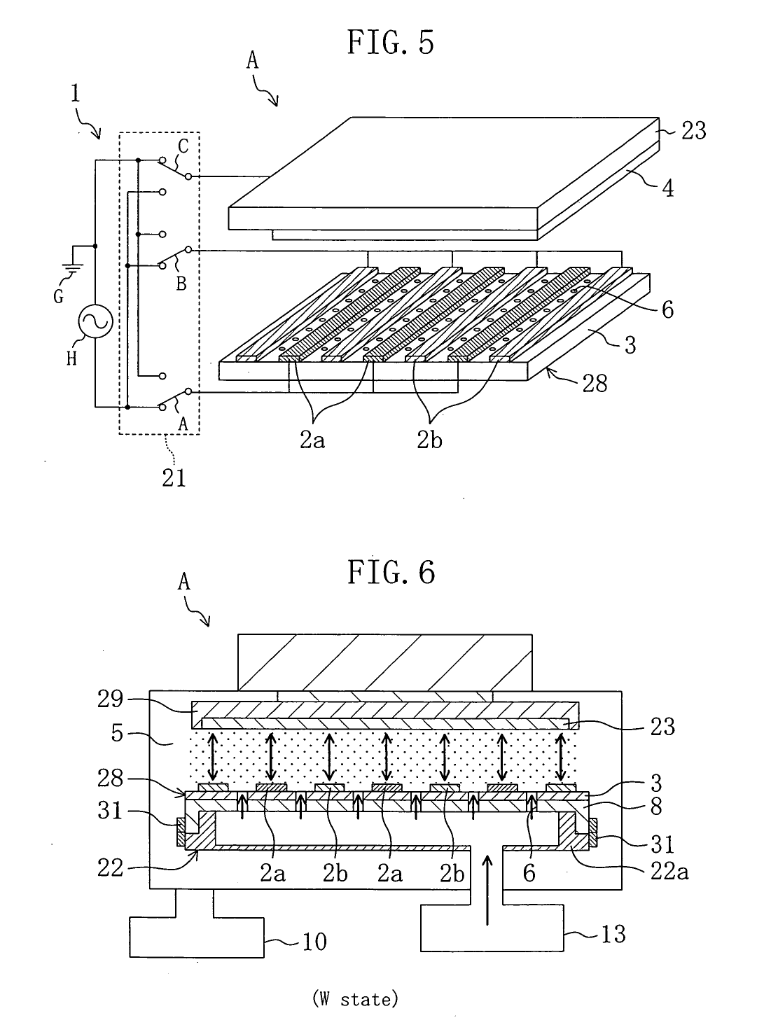

In the first voltage applied state, the first electrodes 2a are connected to the high frequency power source H through the switch A, the second electrodes 2b are connected to the ground G through the switch B and the substrate holder 23 is connected to the ground G through the switch C as shown in FIG. 1. On the other hand, in the second voltage applied state, the connection of the switch B is different from that in the first voltage applied state as shown in FIG. 5, namely, the second electrodes 2b are connected to the high frequency power source H through the switch B.

In other words, the discharge state obtained within the processing chamber 5 is set to a first discharge state (hereinafter referred to as an N state) shown in FIG. 2 when the voltage application is in the first voltage applied state, and is set to a second discharge state (hereinafter referred to as a W state) shown in FIG. 6 when the voltage application is in the second voltage applied state. In the N state, the plasma generated between the first electrodes 2a and the second electrodes 2b is obtained partially in a comparatively narrow region in the vicinity of the composite electrode 28, and hence, the plasma region is reduced to be comparatively narrow. On the other hand, in the W state, the plasma generated between the composite electrode 28 and the substrate holder 23 is obtained in a comparatively wide region within the processing chamber 5, and hence, the plasma region is increased to be comparatively wide.

The cleaning means is composed of the composite electrode 28, the substrate holder 23, the gas supply unit 13 and the vacuum pump 10. When the discharge state is set to the W state, the reaction gas is introduced into the processing chamber 5 by the gas supply unit 13 and the processing chamber 5 is evacuated by the vacuum pump 10, so as to plasma clean the inside of the processing chamber 5.

-Depositing Method and Cleaning Method-

Next, the depositing method and the cleaning method performed by the plasma processing system A will be described. In this embodiment, a depositing operation is performed when the discharge state is set to the N state and a cleaning operation is performed when it is set to the W state.

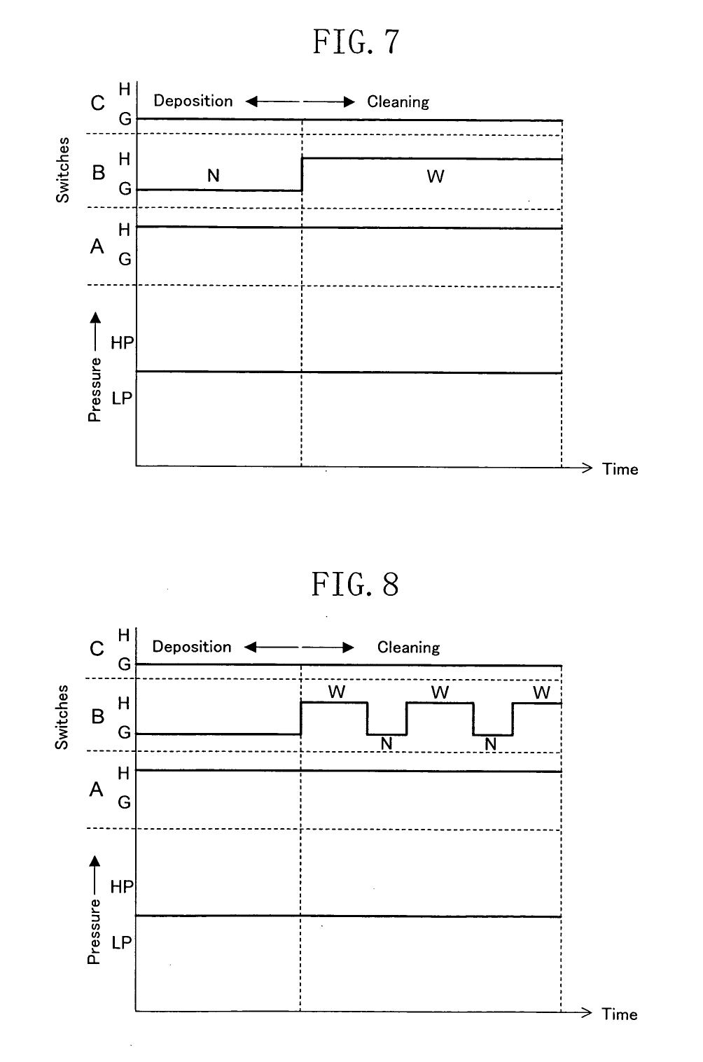

First, in the depositing operation, the target substrate 4 is loaded on the substrate holder 23 as shown in FIG. 2. Subsequently, the voltage applied state of the electrodes 2a and 2b and the substrate holder 23 is switched to the first voltage applied state by the switching device 21 corresponding to the plasma region increasing/reducing means as shown in FIGS. 1 and 7, so as to reduce the plasma region. In this case, the first electrodes 2a work as cathode electrodes and the second electrodes 2b work as anode electrodes. As a result, the discharge state is set to the N state, so as to generate glow discharge plasma having arch-shaped discharge paths formed between first electrodes 2a and second electrodes 2b adjacent to each other as shown with arrows in FIG. 2.

In this N state, the material gas is supplied by the gas supply unit 13 through the gas inlets 6 to the reduced plasma region. The material gas is, for example, a combination of a SiH₄ gas of 900 sccm and a H₂ gas of 2200 sccm. Then, with the temperature of the substrate holder 23 set to 300° C. and the gas pressure within the processing chamber 5 set to 230 Pa, power of 0.8 kW is supplied from the high frequency power source H so as to generate plasma.

The SiH₄ gas is dissociated through the plasma to produce radicals including Si such as SiH₃. These radicals are deposited on the face of the target substrate 4 so as to form an amorphous silicon film (a-Si). In this depositing operation, the spread of the plasma region is small as compared with that obtained in a parallel plate type plasma processing system, and hence, less reaction products are adhered onto the inner walls of the processing chamber 5. Therefore, the plasma cleaning of the inside of the processing chamber 5 can be easily performed as compared with that in the parallel plate type plasma processing system.

In the cleaning operation, the target substrate 4 is previously taken out from the substrate holder 23. Then, the voltage applied state of the electrodes 2a and 2b and the substrate holder 23 is switched by the switching device 21 to the second voltage applied state as shown in FIGS. 5 and 7, so as to increase the plasma region. In this case, both the first electrodes 2a and the second electrodes 2b work as cathode electrodes and the substrate holder 23 works as an anode electrode. As a result, the discharge state is set to the W state, and hence, glow discharge plasma is generated between the first and second electrodes 2a and 2b and the substrate holder 23 as shown with arrows in FIG. 6.

In this W state, the reaction gas is supplied from the gas supply unit 13 through the gas inlets 6 to the increased plasma region. The reaction gas is, for example, a mixed gas of a CF₄ gas (tetrafluoromethane) of 800 sccm and an O₂ gas (oxygen) of 100 sccm. The CF₄ gas is dissociated through the plasma to produce fluorine radicals. The fluorine radicals affect the inner walls of the processing chamber 5, so as to clean the inside of the processing chamber 5. In this case, the plasma is generated with the gas pressure within the processing chamber 5 set to 170 Pa and with power of 2.5 kW applied by the high frequency power source H, so as to perform the plasma cleaning.

The temperature of the substrate holder 23 employed in the plasma cleaning operation is preferably the same as that employed in the depositing operation. If the temperature is different between the cleaning operation and the depositing operation, products deposited on the inner walls of the processing chamber 5 and on the composite electrode 28 tend to peel off and the peeled products are spread within the processing chamber 5 and hence are difficult to remove through the plasma cleaning. Thus, the quality of a film to be deposited may be degraded.

Furthermore, the composite electrode 28 is preferably separately cleaned if necessary. Specifically, the door (not shown) of the processing chamber 5 is opened, the screws 32 that fix the composite electrode 28 on the electrode support 22 are loosened so as to remove the composite electrode 28 from the electrode support 22 as shown in FIGS. 3 and 4. Thereafter, the composite electrode 28 is taken out of the processing chamber 5 for cleaning. After the cleaning, the composite electrode 28 is loaded on the electrode support 22 in procedures reverse to those for taking it out.

-Effects of Embodiment 1-

As described so far, according to this embodiment, since the deposition is performed by using the plasma generated between the first electrodes 2a and the second electrodes 2b of the composite electrode 28, the quality of a deposited film can be improved by eliminating ion impact against the target substrate 4. In addition, since the plasma cleaning is performed within the processing chamber 5 with the plasma region increased by the switching device 21 working as the plasma region increasing/reducing means, the products such as particles can be removed over the whole inside of the processing chamber 5. As a result, the production of particles can be suppressed, so as to improve the quality of a deposited film by preventing a film defect.

Furthermore, since the plasma region increasing/reducing means is composed of the three switches A, B and C corresponding to the switching device 21, the plasma region can be increased or reduced with a simple structure, resulting in reducing the system cost.

Moreover, since the composite electrode 28 is removably provided on the electrode support 22, the composite electrode 28 on which the products are easily adhered can be taken out of the processing chamber 5 to be separately cleaned. As a result, a clean and fresh composite electrode can be rapidly exchanged, and hence, the plasma deposition can be precisely performed without spending time on the plasma cleaning. In other words, the operation time of the plasma processing system can be increased to improve the productivity.

Furthermore, since the first electrodes 2a and the second electrodes 2b of the composite electrode 28 are provided in the shape of stripes, the distances between adjacent electrodes are uniform, so as to obtain stable discharge. Also, since the electrode structure is thus simple, the composite electrode can be easily fabricated.

Embodiment 2

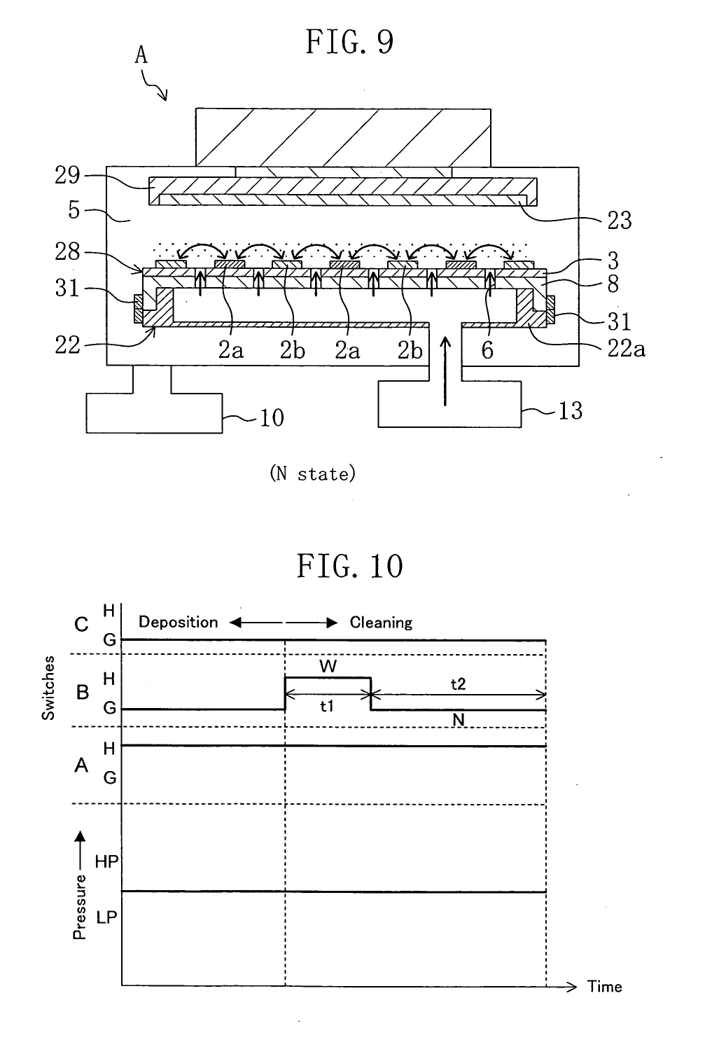

FIGS. 8 and 9 show Embodiment 2 of the present invention. It is noted that like reference numerals are used, in this and each embodiment described below, to refer to like elements shown in FIGS. 1 through 7 so as to omit the detailed description.

While the discharge state is kept to the W state in the cleaning operation in Embodiment 1, the discharge state is alternately changed between the W state and the N state during the cleaning operation in this embodiment. In other words, the switching device 21 of this embodiment switches the voltage applied state alternately between the first voltage applied state and the second voltage applied state during the cleaning operation.

Furthermore, in this embodiment, the cleaning means plasma cleans the inside of the processing chamber by using plasma generated in the plasma region increased or reduced by the plasma region increasing/reducing means 21.

The depositing operation is performed in the same manner as in Embodiment 1 and hence the description is omitted in this and each embodiment described below. In the case where the plasma processing system A is subjected to cleaning, the switch B is intermittently switched as shown in FIG. 8. Specifically, the second electrodes 2b are connected to the high frequency power source H for a given period of time, so as to keep the discharge state to the W state shown in FIG. 6. Thereafter, the second electrodes 2b are connected to the ground G for a given period of time, so as to keep the discharge state to the N state shown in FIG. 9. While this switching operation is repeated by a plurality of times, the reaction gas is introduced from the gas supply unit 13 into the processing chamber 5 for performing the plasma cleaning.

-Effects of Embodiment 2-

Therefore, according to this embodiment, the whole inside of the processing chamber 5 can be cleaned by performing the plasma cleaning with the plasma region increased, and in addition, a portion around the composite electrode 28 can be intensively cleaned by performing the plasma cleaning with the plasma region reduced.

Specifically, as shown in FIG. 9, when the discharge state is set to the N state, products adhered onto the composite electrode 28 can be efficiently removed by substantially 100%, but the efficiency to remove products adhered onto the inner walls of the processing chamber 5 is approximately 70 through 80%. On the contrary, as shown in FIG. 6, when the discharge state is set to the W state, the discharge plasma is spared over the space between the electrodes, and therefore, the products adhered onto the inner walls of the processing chamber 5 can be removed by substantially 100%.

However, the plasma density is different between the W state and the N state. Specifically, in the W state, although the discharge plasma is spread, the plasma density is lower than that of the discharge plasma generated in the N state. As a result, there arises a difference in a removing rate (i.e., an etching rate) for removing the products. When the removing rate for removing the products by substantially 100% is actually compared, the rate obtained in the N state is twice through three times as high as that obtained in the W state. Therefore, when the portion around the composite electrode 28 on which a large number of products are adhered is cleaned in the N state and the inside of the processing chamber 5 is cleaned in the W state, the products can be efficiently removed by substantially 100%.

When the discharge state is switched during one cleaning operation between the W state and the N state by a plurality of times, the deposits within the processing chamber 5 can be wholly removed in a well-balanced manner. Thus, the cleaning can be efficiently performed while suppressing production of reaction products such as particles and dusts.

Embodiment 3

FIG. 10 shows Embodiment 3 of the present invention. While the discharge state is kept to the W state in the cleaning operation in Embodiment 1, the discharge state is kept to the W state or the N state and a period for keeping the N state is longer than a period for keeping the W state in the cleaning operation in this embodiment. In other words, in the cleaning operation, the switching device 21 of this embodiment switches the voltage applied state so that a period for keeping the first voltage applied state can be longer than a period for keeping the second voltage applied state.

The cleaning means performs the plasma cleaning of the inside of the processing chamber 5 by using plasma generated in the plasma region increased or reduced by the plasma region increasing/reducing means corresponding to the switching device 21.

In the case where the plasma processing system A is subjected to the cleaning, the switch B is switched as shown in FIG. 10. Specifically, the second electrodes 2b are connected to the high frequency power source H for a given period of time t1, so as to keep the discharge state to the W state shown in FIG. 6. Thereafter, the second electrodes 2b are connected to the ground G for a given period of time t2 longer than the given period t1, so as to keep the discharge state to the N state shown in FIG. 9. During the period t1 and the period t2, the reaction gas is introduced from the gas supply unit 13 into the processing chamber 5 so as to perform the plasma cleaning.

-Effects of Embodiment 3-

Therefore, according to this embodiment, the inner walls of the processing chamber 5 on which unwanted films are comparatively less adhered are cleaned in the comparatively short period t1 and the composite electrode 28 on which unwanted films are comparatively easily adhered is cleaned over the comparatively long period t2. Therefore, the whole plasma processing system A can be efficiently cleaned.

Embodiment 4

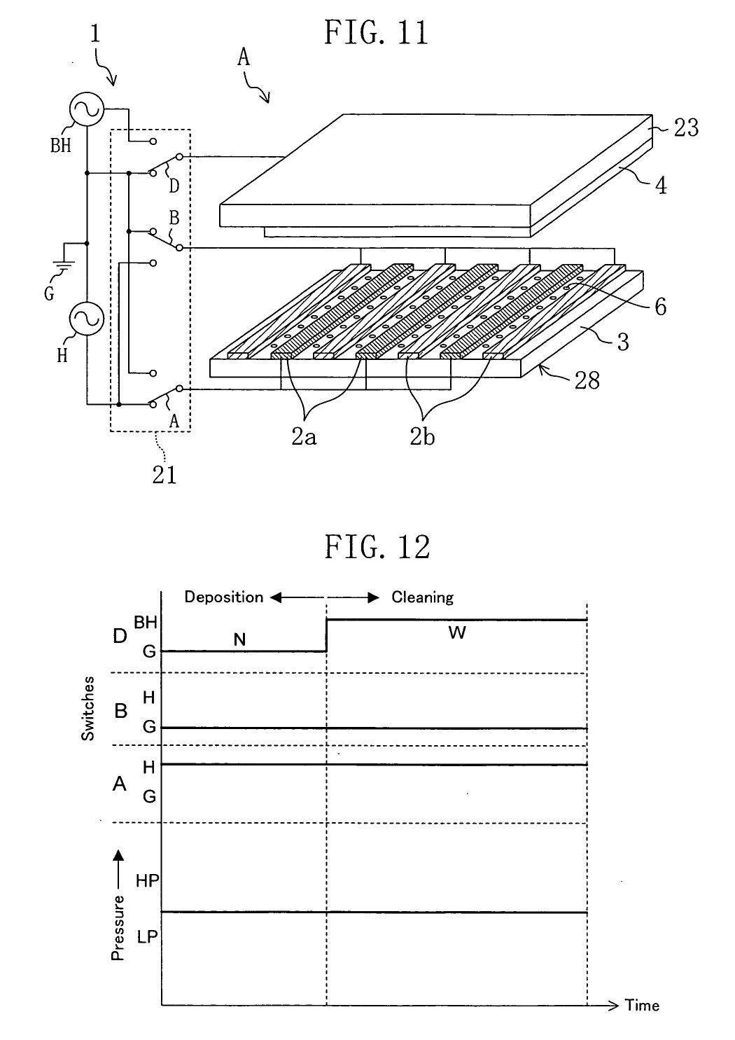

FIGS. 11 and 12 show Embodiment 4 of the present invention. In Embodiment 1, the discharge state obtained in the processing chamber 5 is switched by increasing/reducing the plasma region by using the switching device 21. In contrast, in this embodiment, the plasma region is increased/reduced by applying a bias voltage to the substrate holder 23 so as to switch the discharge state obtained in the processing chamber 5.

The power circuit unit 1 includes, as shown in FIG. 11, a switch D instead of the switch C used in Embodiment 1 and further includes a bias power source BH. The switch D is connected to the substrate holder 23, so as to switch the connection of the substrate holder 23 between the bias power source BH and the ground G. In other words, the plasma region increasing/reducing means of this embodiment is composed of the power circuit unit 1 having the bias power source BH and the switch D.

In the depositing operation, the first electrodes 2a are connected to the high frequency power source H through the switch A, the second electrodes 2b are connected to the ground G through the switch B, and the substrate holder 23 is connected to the ground G through the switch D. On the contrary, in the cleaning operation, the connection of the switch D alone is changed as shown in FIG. 12. Specifically, the substrate holder 23 is connected to the bias power source BH through the switch D. Thus, the discharge state obtained in the processing chamber 5 is changed from the N state shown in FIG. 9 to the W state shown in FIG. 6.

This change of the discharge state is caused in accordance with the Paschen's law. Specifically, according to the Paschen's law, a voltage V at which discharge is started is a function of a product of a surrounding gas pressure P and a discharge path d (namely, V=f(P×d)). Accordingly, when the voltage V is increased with the gas pressure P kept constant, the discharge path d is increased. In this embodiment, since the bias voltage is applied to the substrate holder 23, plasma is generated between the substrate holder 23 and the composite electrode 28 corresponding to a longer discharge path than the discharge path between the adjacent electrodes 2a and 2b of the composite electrode 28. As a result, the discharge state is changed to the W state.

In this manner, the discharge state is changed to the W state by switching the switch D and the reaction gas is introduced into the processing chamber 5, so as to perform the plasma cleaning.

-Effects of Embodiment 4-

Therefore, according to this embodiment, the same effects as those attained in Embodiment 1 can be attained. Furthermore, since the bias voltage can be applied between the composite electrode 28 and the substrate holder 23 in the depositing operation, the quality of a film to be deposited can be controlled. Also, the efficiency of the cleaning operation can be improved.

Embodiment 5

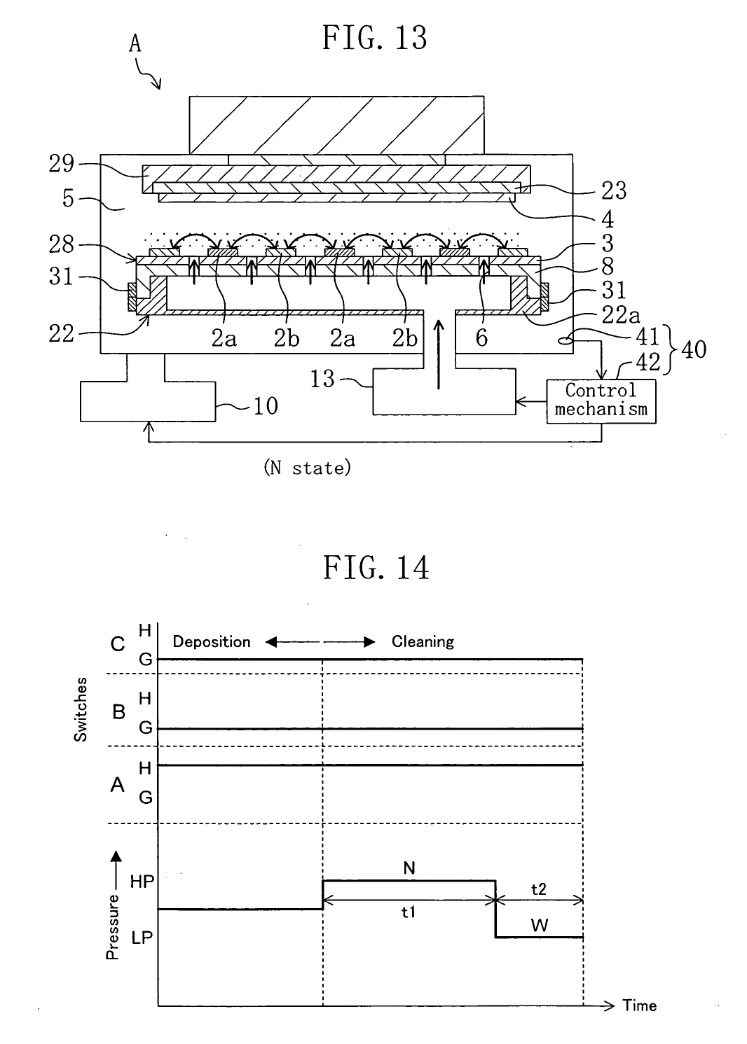

FIGS. 13 and 14 show Embodiment 5 of the present invention. In this embodiment, the plasma region is increased/reduced by changing the gas pressure within the processing chamber 5. Specifically, while the discharge state obtained in the processing chamber 5 is switched by changing the voltage applied state of the electrodes 2a and 2b and the substrate holder 23 by the switching device 21 in Embodiment 1, the discharge state obtained in the processing chamber 5 is switched by changing the pressure within the processing chamber 5 in this embodiment.

The plasma region increasing/reducing means of this embodiment includes, as shown in FIG. 13, a pressure control mechanism 40 for controlling the pressure within the processing chamber 5 to which the reaction gas is supplied by the gas supply unit 13. The pressure control mechanism 40 includes a detection unit 41 for detecting the pressure within the processing chamber 5, and a control unit 42 for controlling the gas supply unit 13 and the vacuum pump 10.

The detection unit 41 is composed of a pressure sensor or the like. The control unit 42 controls, on the basis of a pressure value detected by the detection unit 41, a supply amount of the reaction gas supplied by the gas supply unit 13 and an evacuation amount of the gas evacuated from the processing chamber 5 by the vacuum pump 10. Thus, the pressure within the processing chamber 5 is kept at a given pressure.

In the cleaning operation, the pressure control mechanism 40 controls, as shown in FIG. 14, the gas pressure within the processing chamber 5 to be a comparatively high pressure HP for setting the discharge state to the N state shown in FIG. 9 and controls the gas pressure within the processing chamber 5 to be a comparatively low pressure LP for setting the discharge state to the W state shown in FIG. 6.

Specifically, according to the Paschen's law (i.e., V=f(P×d)), when the voltage V is constant, the discharge path is reduced by increasing the gas pressure P, and therefore, the plasma discharge is caused between the first electrodes 2a and the second electrodes 2b. On the other hand, when the voltage is constant, the discharge path is increased by reducing the gas pressure P, and therefore, the plasma discharge is caused between the first electrodes 2a and the substrate holder 23. Accordingly, the discharge state obtained in the processing chamber 5 is switched to the N state or the W state by changing the gas pressure.

-Depositing Method and Cleaning Method-

In this embodiment, in both the depositing operation and the cleaning operation, the switching device 21 of the power circuit unit 1 is not operated. Specifically, as shown in FIG. 1, the first electrodes 2a are kept to be connected to the high frequency power source H, the second electrodes 2b are kept to be connected to the ground G and the substrate holder 23 is kept to be connected to the ground G. The depositing operation is performed in the same manner as in Embodiment 1. In this case, the gas pressure within the processing chamber 5 is preferably set to, for example, 200 Pa.

In the cleaning operation, the pressure within the processing chamber 5 is increased/reduced by using the pressure control mechanism 40 as shown in FIG. 14. Specifically, the pressure control mechanism 40 controls the pressure within the processing chamber 5 in such a manner that a period for keeping a first predetermined pressure HP is longer than a period for keeping a second predetermined pressure LP lower than the first pressure HP.

More specifically, the pressure control mechanism 40 first controls, as shown in FIG. 14, the gas pressure within the processing chamber 5 to which the reaction gas is supplied to be the comparatively high pressure HP for a given period of time t1, so as to keep the discharge state to the N state. The high pressure HP is preferably, for example, 300 Pa. Thereafter, the pressure control mechanism 40 controls the pressure within the processing chamber 5 to be the comparatively low pressure LP for a given period of time t2, so as to keep the discharge state to the W state. During the period t1 and the period t2, the inside of the processing chamber 5 is plasma cleaned. The low pressure LP is preferably, for example, 120 Pa.

-Effects of Embodiment 5-

Therefore, according to this embodiment, the composite electrode 28 on which unwanted films are comparatively easily adhered can be cleaned over the comparatively long period t1 and the inner walls of the processing chamber 5 to which unwanted films are comparatively less adhered can be cleaned in the comparatively short period t2 in the same manner as in Embodiment 3. Therefore, the whole plasma processing system A can be efficiently cleaned.

Embodiment 6

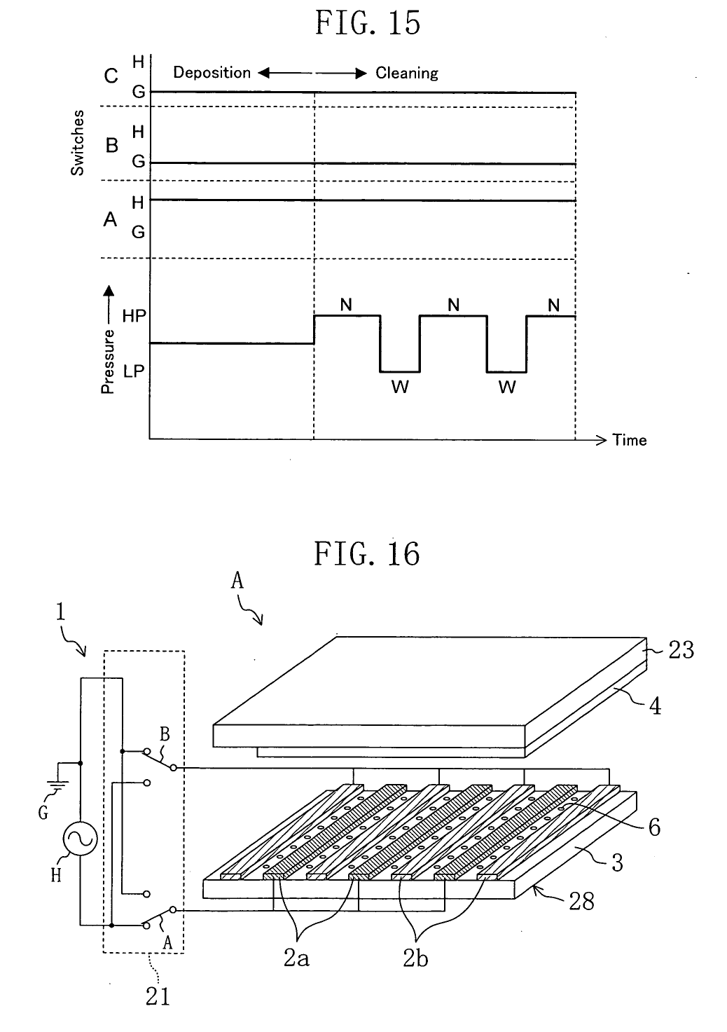

FIG. 15 shows Embodiment 6 of the present invention. While the plasma region is changed to switch the discharge state once during the cleaning operation in Embodiment 5, the plasma region is increased/reduced so as to change the discharge state alternately to the W state and the N state during the cleaning operation in this embodiment. In other words, the pressure control mechanism 40 switches the gas pressure within the processing chamber 5 alternately between the comparatively high pressure HP and the comparatively low pressure LP during the cleaning operation.

-Effects of Embodiment 6-

Therefore, according to this embodiment, the same effects as those attained in Embodiment 2 can be attained. Specifically, when the gas pressure within the processing chamber 5 is the high pressure HP, the discharge state is set to the N state, and therefore, the portion around the composite electrode 28 can be intensively cleaned. On the other hand, when the gas pressure within the processing chamber 5 is the low pressure LP, the discharge state is set to the W state, and therefore, the whole inside of the processing chamber 5 can be cleaned.

Embodiment 7

FIGS. 16 through 18 show Embodiment 7 of the present invention. While the substrate holder 23 works as an electrode in Embodiment 5, the substrate holder 23 does not work as an electrode in this embodiment.

Specifically, the substrate holder 23 of this embodiment is made from an insulating material, and the power circuit unit 1 does not have the switch C as shown in FIG. 16. The first electrodes 2a are kept to be connected to the high frequency power source H and the second electrodes 2b are kept to be connected to the ground G. In the same manner as in Embodiment 5, the discharge state is changed by increasing/reducing the gas pressure within the processing chamber 5 by using the pressure control mechanism 40, so as to clean the inside of the processing chamber 5.

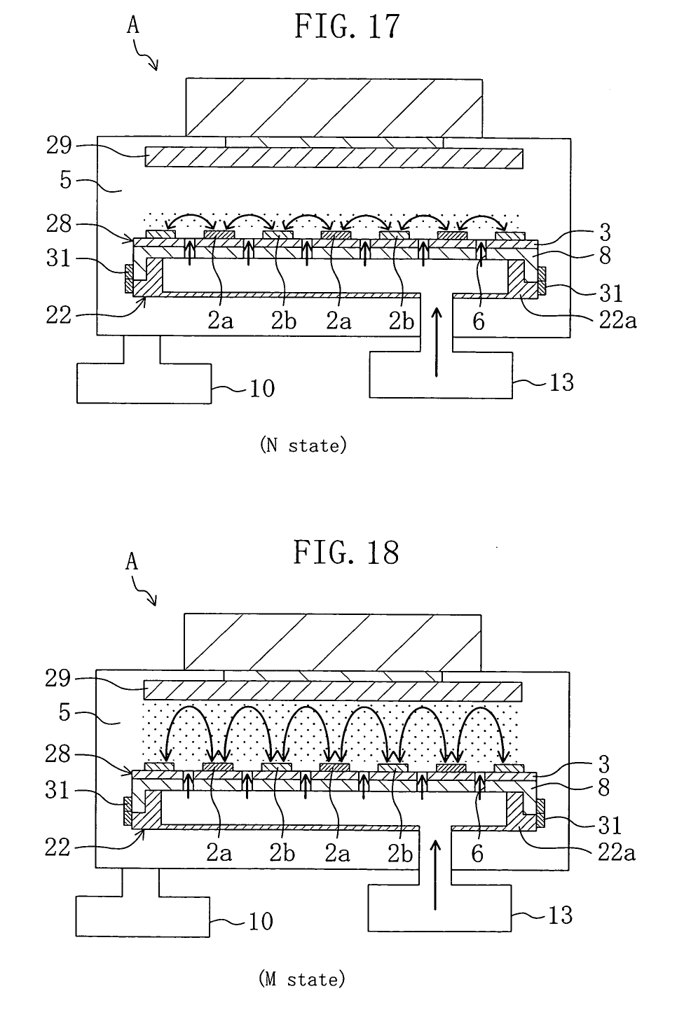

In the cleaning operation, the gas pressure within the processing chamber 5 is kept at the comparatively high pressure HP for a given period of time t1 as shown in FIG. 14. At this point, the discharge state obtained in the processing chamber 5 is set to the N state as shown in FIG. 17, and therefore, the portion around the composite electrode 28 is intensively cleaned. Next, the gas pressure within the processing chamber 5 is kept at the comparatively low pressure LP for a given period of time t2. At this point, the discharge state obtained in the processing chamber 5 is set to a third state (hereinafter referred to as the M state) as shown in FIG. 18.

According to the Paschen's law, the discharge path d is increased as the gas pressure P is reduced, but the plasma discharge is not caused between the first electrodes 2a and the substrate holder 23 even when the gas pressure is lowered because the substrate holder 23 is not an electrode in this embodiment. Specifically, in this M state, the plasma discharge is caused between the first electrodes 2a and the second electrodes 2b and the plasma discharge extends upward as shown in FIG. 18. As a result, the plasma region is increased from that obtained in the N state to that obtained in the M state, and therefore, the whole inside of the processing chamber 5 can be cleaned.

-Effects of Embodiment 7-

Therefore, according to this embodiment, the same effects as those attained in Embodiment 5 can be attained. In addition, since the substrate holder 23 is not an electrode, there is no need to control the polarity of the substrate holder 23, and hence, the configuration of the power circuit unit 1 can be simplified.

Embodiment 8

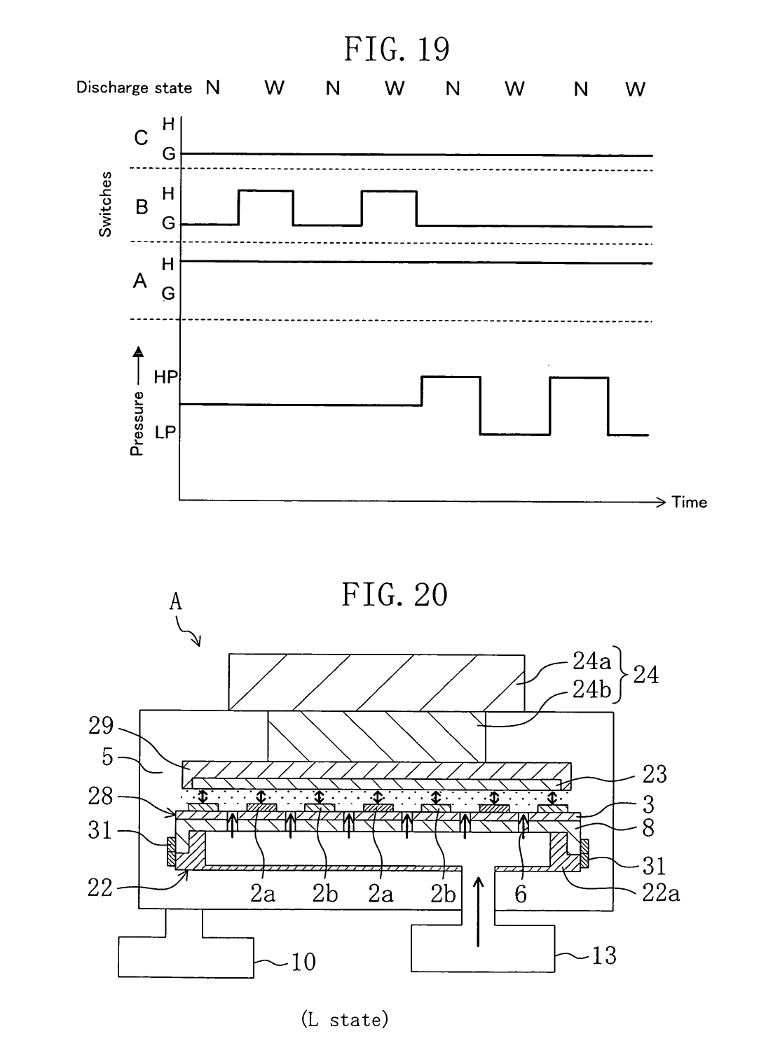

FIG. 19 shows Embodiment 8 of the present invention. In Embodiment 2, the plasma region is increased/reduced by using the switching device 21 alone in the cleaning operation, so as to switch the discharge state alternately between the W state and the N state. In contrast, in this embodiment, the plasma region is increased/reduced by using the switching device 21 and the pressure control mechanism 40, so as to switch the discharge state.

Specifically, the plasma region increasing/reducing means of this embodiment includes the switching device 21 and the pressure control mechanism 40. As shown in a time chart for the cleaning operation of FIG. 19, after the discharge state is switched by using the switching device 21, the discharge state is switched by using the pressure control mechanism 40.

First, with the gas pressure within the processing chamber 5 kept to a given pressure, the voltage applied state of the first electrodes 2a, the second electrodes 2b and the substrate holder 23 is switched, so as to increase or reduce the plasma region. As a result, the discharge state is switched alternately between the N state and the W state.

Thereafter, with the first electrodes 2a connected to the high frequency power source H and with the second electrodes 2b connected to the ground G, the gas pressure within the processing chamber 5 is switched by using the pressure control mechanism 40 alternately between the comparatively high pressure HP and the comparatively low pressure LP. As a result, the plasma region is reduced when the gas pressure is set to the high pressure HP and is increased when the gas pressure is set to the low pressure LP, and therefore, the discharge state is switched alternately between the N state and the W state.

Thus, the same effects as those attained by Embodiments 2 and 6 can be attained.

Embodiment 9

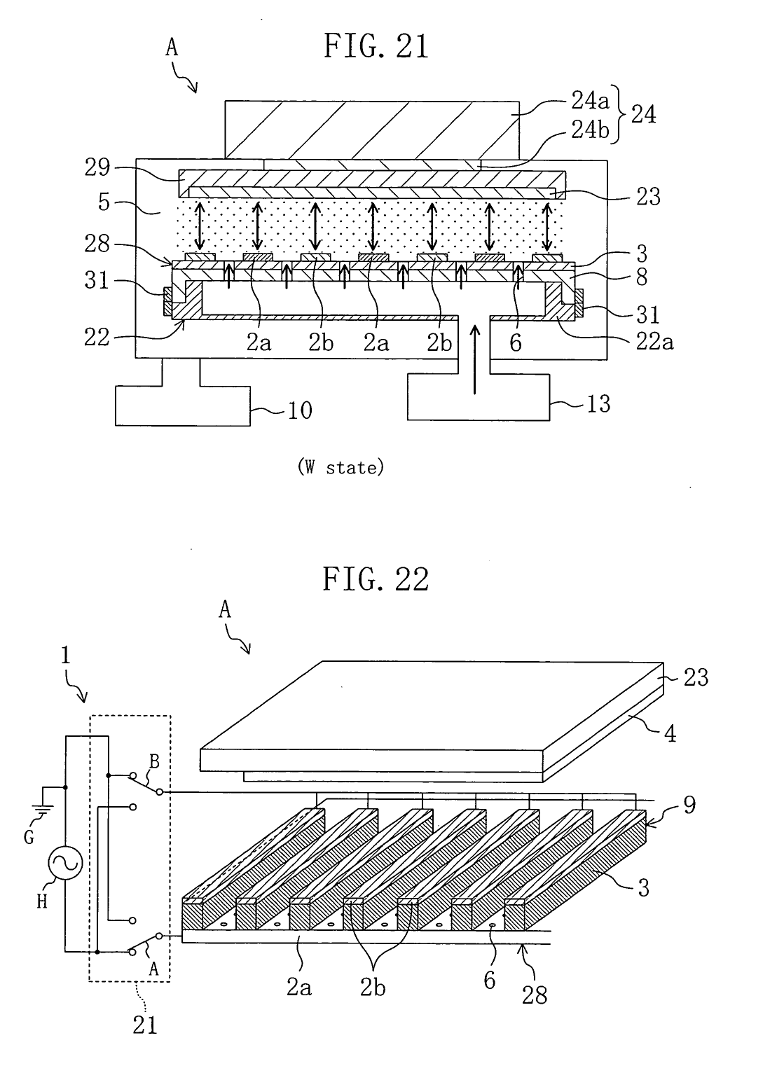

FIGS. 20 and 21 show Embodiment 9 of the present invention. While the plasma region is increased/reduced by using the switching device 21 in Embodiment 1, the plasma region is increased or reduced by using an adjusting mechanism for adjusting the distance between the substrate holder 23 and the composite electrode 28 in this embodiment.

Specifically, the plasma region increasing/reducing means of this embodiment includes an elevating mechanism 24 working as the adjusting mechanism, and the switching device 21. The elevating mechanism 24 includes a body 24a provided on the processing chamber 5 and a stretch part 24b provided below the body 24a and stretchable in the vertical direction within the processing chamber 5. The substrate holder 23 is provided on the lower face of the stretch part 24b with the insulating member 29 sandwiched therebetween. Thus, the substrate holder 23 can be moved in parallel between an upper position shown in FIG. 21 and a lower position shown in FIG. 20.

When the plasma is generated between the composite electrode 28 and the substrate holder 23, the plasma region can be increased/reduced by elevating the substrate holder 23 by using the elevating mechanism 24. Specifically, when the substrate holder 23 is in the upper position shown in FIG. 21, the plasma region is increased and hence the discharge state is set to the W state. On the other hand, when the substrate holder 23 is in the lower position shown in FIG. 20, the plasma region is reduced, and hence the discharge state is set to a fourth state (hereinafter referred to as the L state).

-Depositing Method and Cleaning Method-

In the depositing operation, with the substrate holder 23 disposed in the upper position by the elevating mechanism 24, the deposition is performed in the same manner as in Embodiment 1. Specifically, the voltage applied state of the first electrodes 2a, the second electrodes 2b and the substrate holder 23 is switched to the first voltage applied state by the switching device 21, so as to set the discharge state to the N state shown in FIG. 2. In this N state, the material gas is introduced from the gas supply unit 13 into the processing chamber 5 so as to deposit a film.

In the cleaning operation, the voltage applied state is switched to the second voltage applied state by the switching device 21. Then, as shown in FIG. 21, with the plasma region increased by elevating the substrate holder 23 to the upper position, the plasma cleaning is performed, so as to clean the whole inside of the processing chamber 5. In this case, the distance between the composite electrode 28 and the substrate holder 23 is, for example, 60 mm.

Next, as shown in FIG. 20, with the voltage applied state kept, the substrate holder 23 is lowered to the lower position. Thus, with the plasma region reduced to a portion in the vicinity of the composite electrode 28, the plasma cleaning is performed so as to intensively clean the composite electrode 28. In this case, the distance between the composite electrode 28 and the substrate holder 23 is, for example, 30 mm.

-Effects of Embodiment 9-

Therefore, according to this embodiment, since the plasma region is increased or reduced in the cleaning operation by using the elevating mechanism 24, both the whole inside of the processing chamber 5 and the composite electrode 28 can be suitably subjected to the plasma cleaning. In particular, the composite electrode 28 can be intensively cleaned by reducing the plasma region by lowering the substrate holder 23 to the lower position.

Embodiment 10

FIGS. 22 through 24 show Embodiment 10 of the present invention. This embodiment is different from Embodiment 8 in the structure of the composite electrode 28.

The composite electrode 28 of this embodiment includes, as shown in a schematic perspective view of FIG. 22, a first electrode 2a that is a plate-shaped cathode electrode disposed in parallel to the target substrate 4, and a plurality of convexes 9 disposed on the first electrode 2a at given intervals in parallel to one another. Each convex 9 includes an inter-electrode insulating portion 3 formed on the top face of the first electrode 2a and a second electrode 2b stacked on the inter-electrode insulating portion 3 as an anode electrode. Each convex 9 is in the shape of, for example, a rectangular parallelepiped as a whole. In the first electrode 2a, a plurality of gas inlets 6 penetrating therethrough in the vertical direction are provided between the adjacent convexes 9.

The target substrate 4 is loaded on the substrate holder 23 made from an insulating material. The composite electrode 28 is loaded on the electrode support (not shown) and is connected to the power circuit unit 1 in the same manner as in Embodiment 8. The switch A is connected to the first electrode 2a and the switch B is connected to the second electrodes 2b.

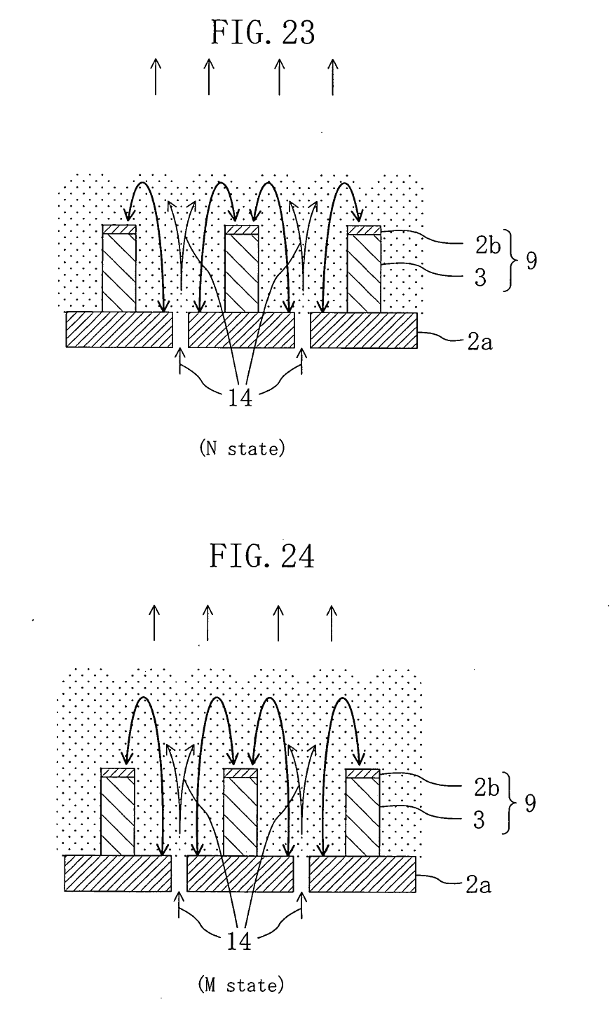

As shown in FIGS. 23 and 24, plasma discharge is caused between the top face of the first electrode 2a exposed between the adjacent convexes 9 and the second electrodes 2b provided on the top faces of the convexes 9.

In other words, the composite electrode 28 includes the first electrode 2a and the second electrodes 2b disposed to be closer to the target substrate 4 than the first electrode 2a, and merely faces of the first electrode 2a and the second electrodes 2b that are visible from the normal direction of the target substrate 4 work as plasma discharge faces. Specifically, when seen from above, the first electrode 2a and the second electrodes 2b are alternately provided in the shape of stripes.

At this point, the plasma discharge face does not mean the face of a material used for the first electrode 2a or the second electrode 2b but means a face substantially working as a discharge electrode that exchanges charged particles (electric charge) with plasma.

-Depositing Method and Cleaning Method-

In the depositing operation, the first electrode 2a is connected to the high frequency power source H through the switch A as shown in FIG. 22. Furthermore, the second electrodes 2b are connected to ground G through the switch B. Thus, the plasma discharge is caused between the second electrode 2b disposed on the top face of each convex 9 and respective faces of the first electrode 2a exposed on both sides of the convex 9 as shown in, for example, FIG. 23.

At this point, a material gas is introduced into the processing chamber 5 through the gas inlets 6 from the gas supply unit (not shown). As shown with arrows 14 in FIG. 23, the material gas is supplied from the gas inlets 6 into portions between the convexes 9. The material gas is dissociated by the plasma discharge in the portions between the convexes 9 so as to produce radicals. The radicals are deposited on the face of the target substrate 4 disposed above.

In the cleaning operation, the pressure within the processing chamber 5 is controlled by the pressure control mechanism (not shown) so as to increase or reduce the plasma region in the same manner as in Embodiment 8. Specifically, according to the Paschen's law, when the gas pressure is increased with the voltage V kept constant, the discharge path d is reduced. As a result, the plasma region is reduced as shown in FIG. 23, and hence, the discharge state is set to the N state. On the other hand, when the gas pressure is reduced, the discharge path d is increased. Therefore, the plasma region is increased as shown in FIG. 24, and hence, the discharge state is set to the M state.

Therefore, first, the gas pressure within the processing chamber 5 is kept at the comparatively high pressure HP for a predetermined period of time. In this case, the discharge state obtained in the processing chamber 5 is set to the N state shown in FIG. 23, and therefore, a portion around the composite electrode 28 is intensively cleaned. Next, the gas pressure within the processing chamber 5 is kept at the comparatively low pressure LP for a predetermined period of time. In this case, the discharge state obtained in the processing chamber 5 is set to the M state shown in FIG. 24, and therefore, the whole inside of the processing chamber 5 is cleaned.

-Effects of Embodiment 10-

Therefore, according to Embodiment 10, the same effects as those attained in Embodiment 8 can be attained. In addition, since the material gas is supplied through the gas inlets 6 into the plasma region formed between adjacent convexes 9, it flows along the discharge path of the plasma region. As a result, since the material gas flows in the plasma over a longer distance, the dissociation of the material gas can be accelerated so as to increase the depositing rate. In other words, a high quality film can be rapidly deposited.

Embodiment 11

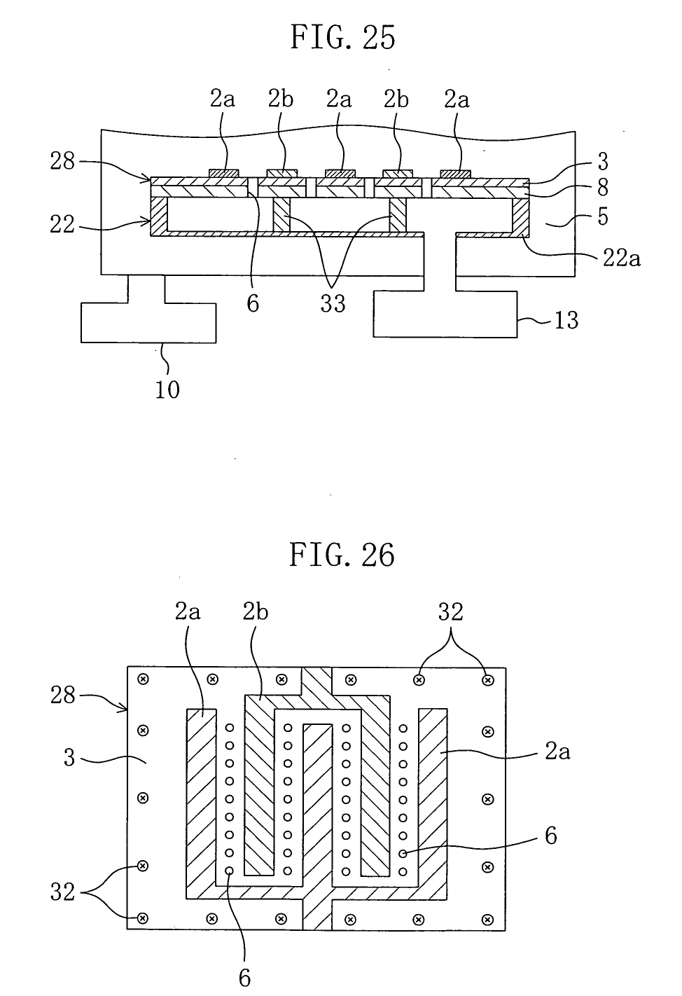

FIGS. 25 through 27 show Embodiment 11 of the present invention. This embodiment is different from Embodiment 1 in the structure for removably providing the composite electrode 28. Specifically, in Embodiment 1, the composite electrode 28 is fit on the electrode support 22 and fixed with the clamps 31 and the screws 32. In contrast, in this embodiment, a plate-shaped composite electrode 28 is placed on an electrode support and fixed with screws 32.

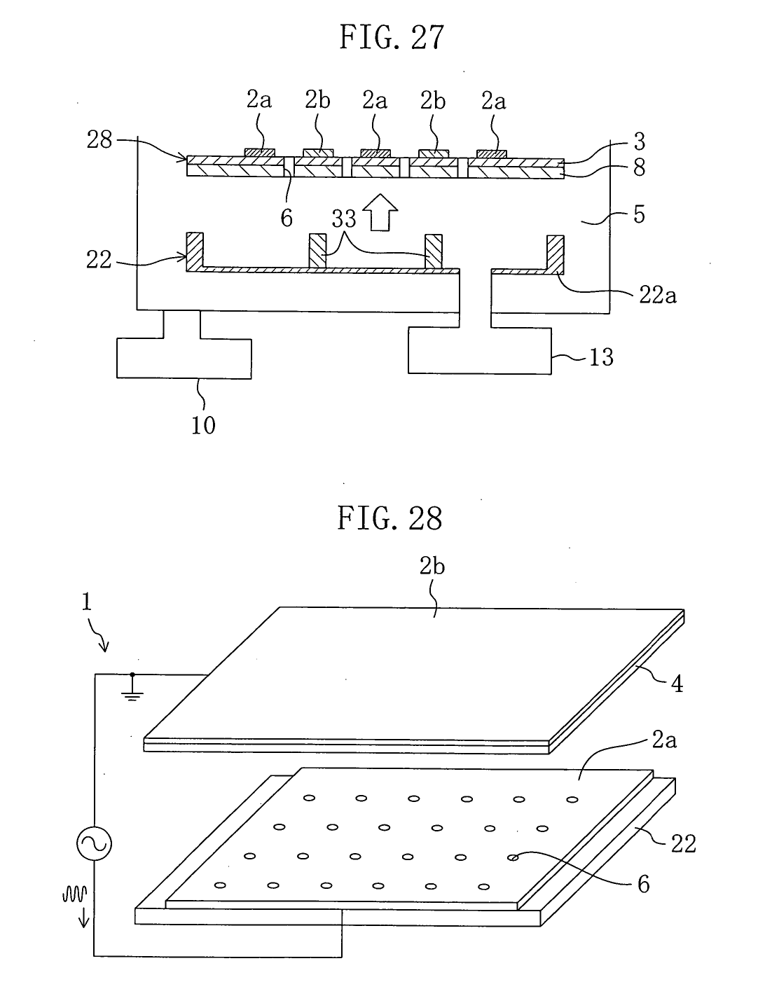

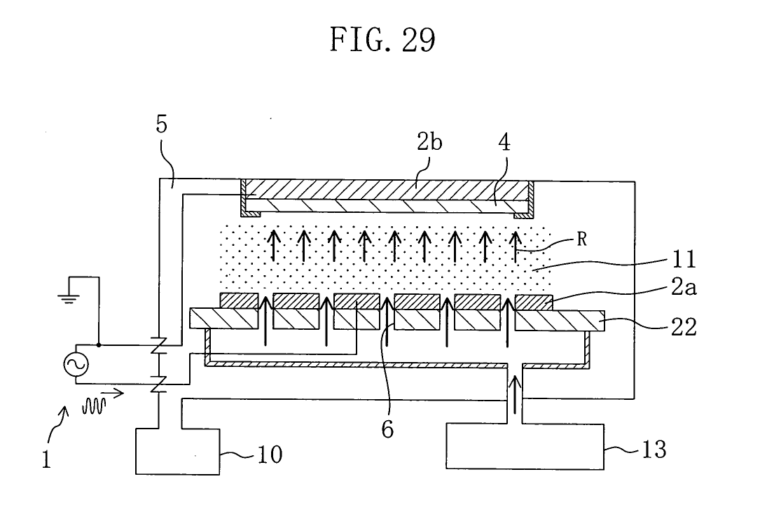

The composite electrode 28 of this embodiment includes, as shown in FIG. 27, a plate-shaped base 8, an inter-electrode insulating portion 3 provided on the base 8, and first electrodes 2a and second electrodes 2b alternately provided on the inter-electrode insulating portion 3 at predetermined intervals.

On the other hand, the electrode support 22 of this embodiment includes a concave 22a opening upward and spacers 33 provided on the bottom of the concave 22a. Each spacer 33 has the same height as the sidewall of the concave 22a, and for example, two spacers 33 are provided to be spaced from each other by a given distance.

When the composite electrode 28 is loaded on the electrode support 22, the base 8 of the composite electrode 28 is placed on the sidewalls and the spacers 33 of the concave 22a as shown in FIG. 25. Thereafter, the composite electrode 28 is fixed on the sidewalls of the concave 22a in the peripheral portion of the composite electrode 28 as shown in a plan view of FIG. 26. Thus, the inside of the concave 22a is closed to work as a chamber. Also, the composite electrode 28 can be easily removed from the electrode support 22 by loosing the screws 32.

Embodiment 12

A plasma processing system according to Embodiment 12 of this invention will now be described with reference to FIGS. 1 through 7.

The plasma processing system of this embodiment has the same structure as that of Embodiment 1 but is different from Embodiment 1 in the depositing operation.

Specifically, the plasma processing system A of this embodiment includes plasma region increasing/reducing means 21 for increasing or reducing a plasma region formed within a processing chamber 5, and a mechanism for depositing a film on a target substrate 4 by using both plasma generated in a plasma region increased by the plasma region increasing/reducing means 21 and plasma generated in a plasma region reduced by the plasma region increasing/reducing means 21.

Furthermore, first depositing process is performed by using plasma generated between first electrodes 2a and second electrodes 2b, and second depositing process is performed by using plasma generated between a substrate holder 23 and the first and second electrodes 2a and 2b.

-Depositing Method-

Now, the depositing method performed by the plasma processing system A of this embodiment will be described. In this embodiment, the first depositing process is performed when the discharge state is set to the N state and the second depositing process is performed when the discharge state is set to the W state.

First, in the first depositing process, the target substrate 4 is loaded on the substrate holder 23 as shown in FIG. 2. Subsequently, as shown in FIGS. 1 and 7, the voltage applied state of the electrodes 2a and 2b and the substrate holder 23 is switched to the first voltage applied state by the switching device 21, that is, the plasma region increasing/reducing means, so as to reduce the plasma region for setting the discharge state to the N state. In this case, the first electrodes 2a work as cathode electrodes and the second electrodes 2b work as anode electrodes. As a result, the discharge state is set to the N state, and glow discharge plasma having an arch-shaped discharge path is generated between the first electrode 2a and the second electrode 2b adjacent to each other as shown with an arrow in FIG. 2.

In this N state, a material gas is supplied from the gas supply unit 13 through the gas inlets 6 to the reduced plasma region. The material gas is, for example, a combination of a SiH₄ gas of 900 sccm and a H₂ gas of 2200 sccm. With the temperature of the substrate holder 23 set to 300° C. and the gas pressure within the processing chamber 5 set to 230 Pa, power of 0.8 kW is supplied from the high frequency power source H, so as to generate plasma.

The SiH₄ gas is dissociated through the plasma so as to produce radicals including Si such as SiH₃. These radicals are deposited on the face of the target substrate 4, so as to form an amorphous silicon film (a-Si). In this depositing operation, the spread of the plasma region is smaller than that in a parallel plate type plasma processing system and the distance between the target substrate 4 and the plasma region is large, and therefore, ion impact against the target substrate 4 can be reduced. Thus, since the ion impact is reduced as compared with that in the parallel plate type plasma processing system, a high quality amorphous silicon film can be formed.

On the other hand, in the second depositing process, the voltage applied state of the electrodes 2a and 2b and the substrate holder 23 is switched to the second voltage applied state by the switching device 21, so as to increase the plasma region for setting the discharge state to the W state. In this case, both the first electrodes 2a and the second electrodes 2b work as cathode electrodes, and the substrate holder 23 works as an anode electrode. As a result, the glow discharge plasma is generated between the first and second electrodes 2a and 2b and the substrate holder 23 as shown with arrows in FIG. 6.

In this W state, a material gas is supplied from the gas supply unit 13 through the gas inlets 6 to the increased plasma region. The material gas is, for example, a mixed gas of a SiH₄ gas of 500 sccm, an NH₃ (ammonia) gas of 1200 sccm and a N₂ (nitrogen) gas of 4000 sccm. With the temperature of the substrate holder 23 set to 300° C. and the gas pressure within the processing chamber 5 set to 150 Pa, power of 2 kW is applied by the high frequency power source H so as to generate plasma. Thus, a silicon nitride (SiN) film is deposited. In this depositing operation, the target substrate 4 is appropriately subjected to ion impact because the plasma region is spread and hence the distance between the target substrate 4 and the plasma region is small. As a result, in deposition of a film such as a silicon nitride film that needs the ion impact for forming a dense film, the film quality can be improved, resulting in forming a high quality silicon nitride film.

The first depositing process and the second depositing process may be alternately performed in a given cycle in accordance with the kinds of films to be deposited. Thus, the film quality can be controlled. Also, the degree of the ion impact can be controlled by increasing/reducing the ratio of a period for performing the second depositing process to a period for performing the first depositing process. Specifically, the ion impact applied to the target substrate 4 can be increased by increasing the ratio of the period for performing the second depositing process to the period for performing the first depositing process. On the other hand, the ion impact applied to the target substrate 4 can be reduced by reducing the ratio of the period for performing the second depositing process.

-Effects of Embodiment 12-

As described above, according to this embodiment, the ion impact against the target substrate 4 can be eliminated by performing the deposition by using the plasma generated between the first electrodes 2a and the second electrodes 2b of the composite electrode 28. Therefore, in depositing a film such as an amorphous silicon film that is degraded through the ion impact, the quality of the deposited film can be improved. In addition, when the deposition is performed with the plasma region increased by using the switching device 21, that is, the plasma region increasing/reducing means, the target substrate 4 can be appropriately subjected to the ion impact. Therefore, in depositing film such as a silicon nitride film that is improved in the quality through the ion impact, the quality of the deposited film can be improved. As a result, the ion impact can be controlled in accordance with the kind of film to be deposited, and therefore, a plurality of different films can be continuously deposited with their qualities improved.

Also, since the plasma region increasing/reducing means is composed of the three switches A, B and C corresponding to the switching device 21, the plasma region can be increased/reduced with a simple structure, resulting in lowering the system cost.

Furthermore, since the first electrodes 2a and the second electrodes 2b of the composite electrode 28 are formed in the shape of stripes, the distances between the electrodes are uniform, and hence, stable discharge can be obtained. Also, the composite electrode 28 has a simple structure, the fabrication can be eased.

Embodiment 13

A plasma processing system according to Embodiment 13 of this invention will now be described with reference to FIGS. 11 and 12.

In Embodiment 12, the discharge state obtained in the processing chamber 5 is switched by increasing/reducing the plasma region by using the switching device 21. In contrast, in this embodiment, the discharge state obtained in the processing chamber 5 is switched by increasing/reducing the plasma region by applying a bias voltage to the substrate holder 23.

Specifically, the plasma processing system of this embodiment has the same structure as that of Embodiment 4, and the power circuit unit 1 includes, as shown in FIG. 11, the switch D instead of the switch C of Embodiment 1 and further includes the bias power source BH. The switch D is connected to the substrate holder 23 so as to switch the connection of the substrate holder 23 between the bias power source BH and the ground G. In other words, the plasma region increasing/reducing means of this embodiment is composed of the power circuit unit 1 having the bias power source BH and the switch D.

-Depositing Method-

The depositing method performed by the plasma processing system A of this embodiment will now be described. Also in this embodiment, first depositing process and second depositing process are performed.

In the first depositing process, the first electrodes 2a are connected to the high frequency power source H through the switch A, the second electrodes 2b are connected to the ground G through the switch B and the substrate holder 23 is connected to the ground G through the switch D. Thus, the discharge state is set to the N state, so that a film can be deposited on the target substrate 4 with the ion impact eliminated.

On the other hand, in the second depositing process, the connection of the switch D alone is changed. Specifically, the substrate holder 23 is connected to the bias power source BH through the switch D. Thus, the discharge state obtained in the processing chamber 5 is switched from the N state shown in FIG. 9 to the W state shown in FIG. 6 in accordance with the Paschen's law.

In this depositing operation, the target substrate 14 is appropriately subjected to the ion impact because the plasma region is spread and hence the distance between the target substrate 4 and the plasma region is small. As a result, in depositing a film such as a silicon nitride film that needs the ion impact for forming a dense film, the quality of the deposited film can be improved, and hence, a high quality silicon nitride film can be formed.

-Effects of Embodiment 13-

Therefore, according to this embodiment, the same effects as those attained in Embodiment 12 can be attained. Specifically, the ion impact can be controlled by increasing/reducing the plasma region by applying a bias voltage between the composite electrode 28 and the substrate holder 23 by switching the switch D. As a result, since the ion impact can be eliminated or not eliminated in accordance with the kind of film to be deposited, a plurality of different films can be continuously deposited by using one and the same system with their qualities improved.

Embodiment 14

A plasma processing system according to Embodiment 14 of the present invention will now be described with reference to FIGS. 22 through 24.

The plasma processing system of this embodiment includes a composite electrode 28 identical to that of Embodiment 10. Specifically, the composite electrode 28 of this embodiment includes a plate-shaped first electrode 2a working as a cathode electrode, a plurality of inter-electrode insulating portions 3 provided on the first electrode 2a at equal intervals and second electrodes 2b stacked on the respective inter-electrode portions 3 working as anode electrodes.

-Depositing Method-

In this embodiment, first depositing process is performed when the discharge state is set to the N state and second depositing process is performed when it is set to the W state as shown in FIG. 23.

In the first depositing process, the first electrode 2a is connected to the high frequency power source H through the switch A as shown in FIG. 22. Furthermore, the second electrodes 2b are connected to ground G through the switch B. The substrate holder 23 is connected to the ground G. In this case, the plasma discharge is caused between the second electrode 2b formed on the top face of each convex 9 and the first electrodes 2a exposed on both sides of the convex 9 as shown in, for example, FIG. 23.

Furthermore, a material gas is introduced by the gas supply unit (not shown) through the gas inlets 6 into the processing chamber 5. As shown with arrows 14 in FIG. 23, the material gas is supplied through the gas inlets 6 into portions between the convexes 9. The material gas is dissociated by the plasma discharge in the portions between the convexes 9 so as to produce radicals. These radicals are deposited on the face of the target substrate 4 disposed above. Thus, a film can be deposited on the target substrate 4 without causing ion impact.

On the other hand, in the second depositing process, the second electrodes 2b are connected to the high frequency power source H through the switch B. The plasma discharge is caused between the composite electrode 28 and the substrate holder 23, and hence the plasma region is increased because the discharge state is set to the W state. Thus, a silicon nitride film or the like can be precisely deposited with appropriate ion impact against the target substrate 4.

-Effects of Embodiment 14-

Therefore, according to Embodiment 14, the dissociation of the material gas is accelerated to increase the depositing rate, and hence, a high quality film can be rapidly deposited. In addition, since the ion impact can be controlled in accordance with the kind of film to be deposited, a plurality of different films can be continuously deposited with their qualities improved.

Alternative Embodiments

In Embodiment 1, the frequency of the voltage supplied by the high frequency power source H may be a high frequency (of the VHF band) of 13.56 MHz or more. For example, the frequency is preferably 27.12 MHz. Thus, the rate for depositing a film on the target substrate 4 can be increased, so as to perform high speed deposition. However, the appropriate upper limit of the frequency is 300 MHz. This is because the limit of the effect to increase electron density by capturing electrons in a portion between the first electrode 2a and the second electrode 2b corresponds to 300 MHz. Also, this is because it is difficult to actually apply high frequency power of 300 MHz or more.

Alternatively, the frequency of the voltage supplied by the high frequency power source H may be a low frequency lower than 13.56 MHz. In this invention, a plasma region is minimally formed in the vicinity of the face of the target substrate in the depositing operation, and therefore, even when the frequency is lower than 13.56 MHz, there is small influence of plasma damage, which causes a problem in a parallel plate type plasma processing system. However, the appropriate lower limit of the frequency is 100 kHz. This is because the limit of the effect to increase ion density by capturing ions in a portion between the first electrode 2a and the second electrode 2b corresponds to 100 kHz.

Also, although the combination of the CF₄ gas and the O₂ gas is used as the reaction gas, the reaction gas may be a combination of a SF₆ gas (sulfur hexafluoride) and an O₂ gas instead. Alternatively, a combination of a NF₃ gas (nitrogen trifluoride) and an Ar gas (argon) or a combination of a NF₃ gas and a CHF₃ gas (trifluoromethane) may be used as the reaction gas.

Furthermore, in each of Embodiments 2, 3, 5 and 7, the elevating mechanism 24 may be provided. Specifically, when the plasma region is increased in the cleaning operation by using the switching device 21 or the pressure control mechanism 40, the substrate holder 23 is moved to the upper position by the elevating mechanism 24. Thus, the plasma region can be further increased.

Moreover, although the plasma region is increased/reduced by the pressure control mechanism 40 in the plasma processing system including the composite electrode 28 having the convexes 9 of Embodiment 10, the pressure control mechanism 40 may be replaced with the switching device 21. Specifically, the substrate holder 23 may be constructed as an electrode as in Embodiment 1 and be connected to the power circuit unit 1 through the switch C. Thus, in the cleaning operation, the switch B connected to the second electrodes 2b is switched, so as to generate the plasma between the composite electrode 28 and the substrate holder 23. Also in this manner, the plasma region can be reduced in the depositing operation and increased in the cleaning operation, and therefore, the same effects as those attained in Embodiment 10 can be attained.

Although the composite electrode 28 is disposed below the substrate holder 23 in the plasma processing system of each of the aforementioned embodiments, this does not limit the invention. The composite electrode 28 may be disposed above the substrate holder 23, or the composite electrode 28 may be disposed to oppose the substrate holder 23 in the horizontal direction in the plasma processing system.

Furthermore, although the ion impact is controlled to deposit different kinds of films in each of Embodiments 12 through 14, the ion impact may be controlled in depositing the same kind of films. For example, in a device utilizing a bonding interface between different kinds of films (such as a TFT or a solar battery), a film may be deposited without ion impact for a given period of time at the start for preventing the bonding interface from being damaged and be deposited with the ion impact applied for a given period of time thereafter. This may be applied to a case where, for example, a silicon nitride film is deposited on an amorphous silicon film.

Moreover, although the depositing method alone is described in each of Embodiments 12 through 14, the cleaning operation described in any of Embodiments 1 through 11 may be performed after depositing a film by the depositing method. Specifically, a film is deposited on the target substrate 4 with the plasma region increased or reduced by the plasma region increasing/reducing means 21 within the processing chamber 5 in the depositing operation, and in the cleaning operation, the inside of the processing chamber 5 may be subjected to the plasma cleaning with the plasma region increased by the plasma region increasing/reducing means 21.

As described so far, the present invention is useful for a plasma processing system for performing plasma processing in a processing chamber by the plasma CVD, and a plasma cleaning method for the system. In particular, the invention is suitably employed for improving the quality of a film to be deposited by eliminating ion impact against a target substrate and for lowering the system cost with a simple structure by efficiently removing particles from the processing chamber.

1. A plasma processing system comprising:
a processing chamber;
a substrate holder provided within said processing chamber for holding a target substrate;
a composite electrode provided within said processing chamber to oppose said substrate holder and having a plurality of discharge electrodes for generating plasma;
material gas supply means for supplying a material gas into said processing chamber;
plasma region increasing/reducing means for increasing or reducing a plasma region formed within said processing chamber; and
cleaning means for plasma cleaning an inside of said processing chamber by using plasma generated in said plasma region increased or reduced by said plasma region increasing/reducing means.

2. The plasma processing system of claim 1,
wherein said cleaning means includes reaction gas supply means for supplying, into said processing chamber, a reaction gas to be used for plasma cleaning the inside of said processing chamber, and
said plasma region increasing/reducing means includes a pressure control mechanism for controlling a pressure within said processing chamber to which the reaction gas is supplied by said reaction gas supply means.

3. The plasma processing system of claim 2,
wherein said pressure control mechanism increases or reduces the pressure within said processing chamber.

4. The plasma processing system of claim 2,
wherein said pressure control mechanism controls the pressure within said processing chamber in such a manner that a period when a given first pressure is kept is longer than a period when a second pressure lower than said first pressure is kept.

5. The plasma processing system of claim 1,
wherein said substrate holder is constructed as an electrode, and
said plasma region increasing/reducing means includes a switching device for switching a voltage applied state of said substrate holder and said discharge electrodes between a first voltage applied state for generating plasma between said discharge electrodes and a second voltage applied state for generating plasma between said composite electrode and said substrate holder.

6. The plasma processing system of claim 5,
wherein said switching device switches said voltage applied state alternately between said first voltage applied state and said second voltage applied state.

7. The plasma processing system of claim 5,
wherein said switching device switches said voltage applied state in such a manner that a period when said first voltage applied state is kept is longer than a period when said second voltage applied state is kept.

8. The plasma processing system of claim 1,
wherein said plasma region increasing/reducing means includes an adjusting mechanism for adjusting a distance between said substrate holder and said composite electrode.

9. The plasma processing system of claim 1,
wherein said composite electrode is removably provided in said processing chamber.

10. The plasma processing system of claim 1,
wherein said composite electrode includes an inter-electrode insulating portion for insulating said plurality of discharge electrodes from one another, and
said plurality of discharge electrodes include first electrodes and second electrodes alternately arranged.

11. The plasma processing system of claim 10,
wherein said first electrodes and said second electrodes are formed in the shape of stripes extending in parallel to one another.

12. The plasma processing system of claim 1,
wherein said composite electrode includes a first electrode and a second electrode disposed closer to said target substrate than said first electrode, and
merely faces of said first electrode and said second electrode visible from a normal direction of said target substrate function as plasma discharge faces.

13. The plasma processing system of claim 12,
wherein said first electrode and said second electrode are formed in the shape of stripes extending in parallel to one another.

14. The plasma processing system of claim 1,
wherein a voltage applied to said composite electrode has a frequency not less than 100 kHz and not more than 300 MHz.

15. A plasma processing system comprising:
a processing chamber;
a substrate holder provided within said processing chamber for holding a target substrate;
a composite electrode provided within said processing chamber to oppose said substrate holder and having a plurality of discharge electrodes for generating plasma;
material gas supply means for supplying a material gas into said processing chamber; and
plasma region increasing/reducing means for increasing or reducing a plasma region formed within said processing chamber,
wherein a film is deposited on said target substrate by using plasma generated in said plasma region increased or reduced by said plasma region increasing/reducing means.

16. The plasma processing system of claim 15,
wherein said substrate holder is constructed as an electrode, and
said plasma region increasing/reducing means includes a switching device for switching a voltage applied state of said substrate holder and said discharge electrodes between a first voltage applied state for generating plasma between said discharge electrodes and a second voltage applied state for generating plasma between said composite electrode and said substrate holder.

17. The plasma processing system of claim 15,
wherein said plasma region increasing/reducing means includes an adjusting mechanism for adjusting a distance between said substrate holder and said composite electrode.

18. The plasma processing system of claim 15,
wherein said composite electrode includes an inter-electrode insulating portion for insulating said plurality of discharge electrodes from one another, and
said plurality of discharge electrodes include first electrodes and second electrodes alternately arranged.

19. The plasma processing system of claim 18,
wherein said first electrodes and said second electrodes are formed in the shape of stripes extending in parallel to one another.

20. The plasma processing system of claim 15,
wherein said composite electrode includes a first electrode and a second electrode disposed closer to said target substrate than said first electrode, and
merely faces of said first electrode and said second electrode visible from a normal direction of said target substrate function as plasma discharge faces.

21. The plasma processing system of claim 20,
wherein said first electrode and said second electrode are formed in the shape of stripes extending in parallel to one another.

22. The plasma processing system of claim 15,
wherein a voltage applied to said composite electrode has a frequency not less than 100 kHz and not more than 300 MHz.

23. A cleaning method for a plasma processing system for cleaning an inside of a processing chamber of said plasma processing system,
said plasma processing system including a substrate holder provided within said processing chamber for holding a target substrate, a composite electrode provided within said processing chamber to oppose said substrate holder and having a plurality of discharge electrodes for generating plasma, and material gas supply means for supplying a material gas into said processing chamber,
said cleaning method comprising a step of removing products from said processing chamber by supplying a cleaning reaction gas into said processing chamber with a plasma region formed in said processing chamber increased or reduced.

24. The cleaning method for a plasma processing system of claim 23,
wherein said cleaning reaction gas used for plasma cleaning the inside of said processing chamber is supplied into said processing chamber and said plasma region is increased or reduced by controlling a pressure within said processing chamber.

25. The cleaning method for a plasma processing system of claim 24,
wherein the pressure within said processing chamber is increased or reduced.

26. The cleaning method for plasma processing system of claim 24,
wherein the pressure within said processing chamber is controlled in such a manner that a period when a given first pressure is kept is longer than a period when a second pressure lower than said first pressure is kept.

27. The cleaning method for plasma processing system of claim 23,
wherein said plasma region is increased or reduced by switching a voltage applied state of said substrate holder constructed as an electrode and said plurality of discharge electrodes between a first voltage applied state for generating plasma between said discharge electrodes and a second voltage applied state for generating plasma between said composite electrode and said substrate holder.

28. The cleaning method for a plasma processing system of claim 27,
wherein said voltage applied state is switched alternately between said first voltage applied state and said second voltage applied state.

29. The cleaning method for a plasma processing system of claim 27,
wherein said voltage applied state is switched in such a manner that a period when said first voltage applied state is kept is longer than a period when said second voltage applied state is kept.
